(19) United States
(12) Patent Application Publication
(10) Pub. No.: US 2026/0321207 A1
(43) Pub. Date: Oct. 15, 2026

(54) DISPLAY DEVICE AND ELECTRONIC DEVICE

(71) Applicant: Samsung Display Co., Ltd., Yongin-Si (KR)

(72) Inventors: Hyeon Sik KIM, Yongin-si (KR); Go Een JEONG, Yongin-si (KR); Soo Yeong HONG, Yongin-si (KR)

(21) Appl. No.: 19/452,405

(22) Filed: Jan. 19, 2026

(30) Foreign Application Priority Data
Apr. 14, 2025 (KR) 10-2025-0047820

(51) Int. Cl. G09G 3/3233; G09G 3/32

(52) U.S. Cl. CPC G09G 3/3233; G09G 3/32; G09G 2300/0426; G09G 2300/0439; G09G 2300/0819; G09G 2300/0842

(57) ABSTRACT

Disclosed herein are a display device and an electronic device with improved sensing capability. The display device includes: a pixel comprising a pixel circuit and a light-emitting element connected to the pixel circuit; a photo sensor comprising a photo sensor circuit and a photoelectric conversion element connected to the photo sensor circuit; wherein the pixel circuit includes a first transistor that is connected to the light-emitting element; and the photo sensor circuit includes a first sensor transistor that is connected to the photo sensor. The first sensor transistor includes a gate electrode connected to the photo sensor and a counter gate electrode connected to a reset voltage line.

This application claims priority from Korean Patent Application No. 10-2025-0047820 filed on Apr. 14, 2025 in the Korean Intellectual Property Office, the disclosure of which is incorporated herein by reference in its entirety.

### BACKGROUND

### 1. Field of the Disclosure

The present disclosure relates to a display device, and more particularly, to a display device and an electronic device having improved sensing capability.

### 2. Description of Related Art

Display devices are becoming increasingly important as multimedia technology evolves. Accordingly, a variety of display devices such as liquid-crystal display devices and organic light-emitting display devices are currently being developed.

### SUMMARY

Aspects of the present disclosure provide a display device with improved sensing capability, and an electronic device.

According to an aspect of the present disclosure, a display device is presented. The display device includes: a pixel comprising a pixel circuit and a light-emitting element connected to the pixel circuit; and a photo sensor comprising a photo sensor circuit and a photoelectric conversion element connected to the photo sensor circuit; wherein the pixel circuit includes a first transistor that is connected to the light-emitting element, and the photo sensor circuit includes a first sensor transistor that is connected to the photo sensor. The first sensor transistor includes a gate electrode connected to the photo sensor and a counter gate electrode connected to a reset voltage line.

According to another aspect of the present disclosure, there is provided an electronic device including a display device for providing a display screen. The display device includes: a pixel comprising a pixel circuit and a light-emitting element connected to the pixel circuit; a photo sensor comprising a photo sensor circuit and a photoelectric conversion element connected to the photo sensor circuit; wherein the pixel circuit includes a first transistor that is connected to the light-emitting element; and the photo sensor circuit includes a first sensor transistor that is connected to the photo sensor. The first sensor transistor includes a gate electrode connected to the photo sensor and a counter gate electrode connected to a reset voltage line.

According to an embodiment of the present disclosure, the sensing capability of a photo sensor of a display device can be improved.

For example, according to an embodiment, a sensor transistor of the photo sensor may be a double-gate transistor including two gate electrodes. As a large negative voltage is applied to a counter gate electrode of the sensor transistor, the threshold voltage of the sensor transistor may be shifted further in the positive direction. As a result, the current amount of the sensor transistor increases, and the sensing capability of that sensor transistor can be improved.

The effects of the present disclosure are not limited to the above-described effects and other effects which are not described herein will become apparent to those skilled in the art from the following description.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a plan view showing a display device according to an embodiment of the present disclosure.

FIG. 2 is a block diagram of a display device according to an embodiment of the present disclosure.

FIG. 3 is a cross-sectional view of the active area of the display device according to the embodiment for illustrating a method for detecting the fingerprint of a finger.

FIG. 4 is a cross-sectional view of the active area of the display device according to the embodiment for illustrating a method for detecting the fingerprint of a finger.

FIG. 5 is a circuit diagram of a pixel and a photo sensor according to an embodiment.

FIG. 6 is a plan view showing the layout of pixels and photo sensors according to an embodiment.

FIG. 7 is a plan view showing the layout of pixels and photo sensors according to another embodiment.

FIG. 8 is a cross-sectional view showing an example of the cross-section of the display device taken along line I – I' of FIG. 6.

FIG. 9 is a view showing a layout of a display device according to an embodiment of the present disclosure.

FIG. 10 is a cross-sectional view showing an example of a cross-section of the display device, taken along line II - II' of FIG. 9.

FIG. 11 is a block diagram of an electronic device according to an embodiment of the present disclosure.

FIGS. 12, 13 and 14 are views showing electronic devices according to a variety of embodiments of the present disclosure.

### DETAILED DESCRIPTION OF THE EMBODIMENTS

The inventive concept will now be described more fully hereinafter with reference to the accompanying drawings, which depict embodiments of the inventive concept. This disclosure may, however, be embodied in different forms and should not be construed as limited to the embodiments set forth herein. Rather, these embodiments are provided so that this disclosure will be thorough and complete, and will fully convey the scope of the disclosure to those skilled in the art.

It will be understood that when a layer is referred to as being "on" another layer or substrate, it can be directly on the other layer or substrate, or intervening layers may be present. The same reference numbers indicate the same components throughout the specification. In the attached figures, the thickness of layers and regions is exaggerated for clarity.

Although the terms "first", "second", etc. may be used herein to describe various elements, these elements should not be limited by these terms. These terms may be used to distinguish one element from another element. Thus, a first element discussed below may be termed a second element without departing from teachings of one or more embodiments. The description of an element as a "first" element may not require or imply the presence of a second element or other elements. The terms "first", "second", etc. may also be used herein to differentiate different categories or sets of elements, without necessarily conveying an order or level of importance. For conciseness, the terms "first", "second", etc. may represent "first-category (or first-set)", "second-category (or second-set)", etc., respectively.

Features of various embodiments of the present disclosure may be combined partially or totally. As will be clearly appreciated by those skilled in the art, technically various interactions and operations are possible. Various embodiments can be practiced individually or in combination.

Hereinafter, specific exemplary embodiments will be described with reference to the accompanying drawings.

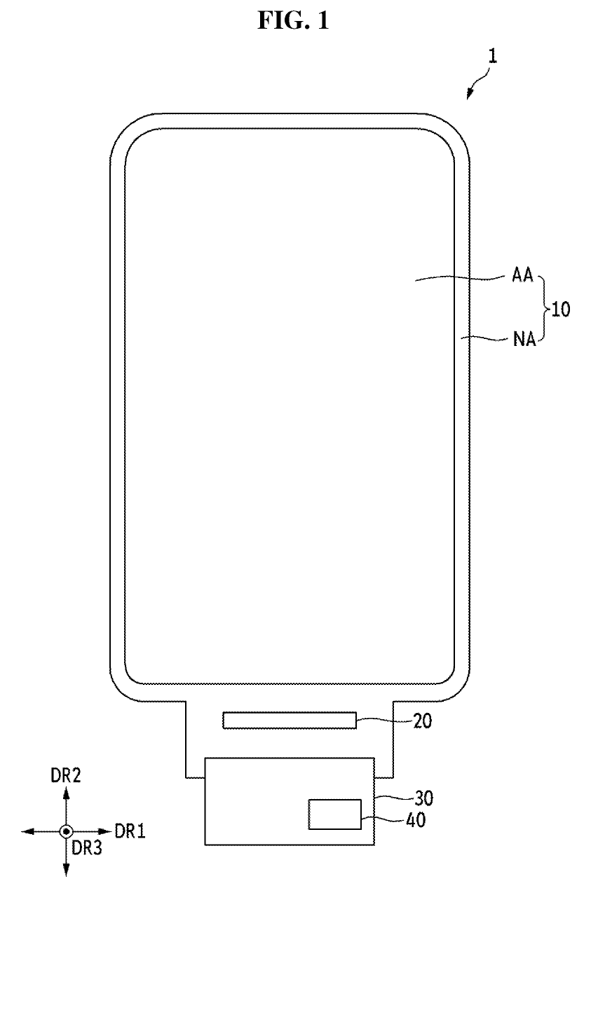

FIG. 1 is a plan view showing a display device 1 according to an embodiment of the present disclosure.

FIG. 1 indicates a first direction DR1, a second direction DR2 and a third direction DR3. The first direction DR1 may refer to a direction parallel to a side of the display device 1, for example, the horizontal direction of the display device 1 when viewed from the top. The second direction DR2 may refer to a direction parallel to another side of the display device 1 that meets the side of the display device 1, for example, the vertical direction of the display device 1 when viewed from the top. The third direction DR3 may be a thickness direction (or height direction) of the display device 1. It should be understood that the directions referred to in the embodiments are relative directions, and the embodiments are not limited thereto.

In addition, in some embodiments, the terms "top," "upper surface," etc. in the third direction DR3 may refer to the display surface side of a display panel 10, whereas the terms "bottom," "lower surface," "rear surface", etc. in the third direction DR3 may refer to the back or opposite side of the display panel 10. It should be understood, however, that the defined directions may be changed to the opposite directions, etc., depending on the direction in which the display panel 10 or the display device 1 including the display panel 10 is viewed.

Referring to FIG. 1, the display device 1 may be one of a variety of electronic devices that provides a display surface on which images are displayed. For example, the display device 1 may be one of a variety of electronic devices including a mobile phone, a smart phone, a tablet PC, a mobile communications terminal, an electronic organizer, an e-book, a personal digital assistant (PDA), a portable multimedia player (PMP), a navigation device, an ultra mobile PC (UMPC), a television set, a game machine, a wristwatch-type electronic device, a head-mounted display, a personal computer monitor, a laptop computer, a vehicle instrument cluster, a digital camera, a camcorder, an outdoor billboard, an electronic billboard, various medical apparatuses, various inspection devices, various home appliances including a display area such as a refrigerator and a laundry machine, Internet of things (IoT) devices, etc. Although a smartphone, a tablet PC, a laptop computer, etc., are described as examples of the display device 1, the display device 1 according to the embodiments of the present disclosure is not limited to devices that are used as examples.

The display device 1 may include a display panel 10, a driver circuit 20, a circuit board 30, and a read-out circuit 40 (e.g., read-out IC).

The display panel 10 may include an active area AA and a non-active area NA. According to an embodiment of the present disclosure, the display panel 10 may be partially or entirely flexible and may be folded, bent, rolled or otherwise transformed into a different shape at least partially. For example, the display panel 10 may be folded or bent in the non-active area NA, and accordingly, a portion of the non-active area NA in which the driver circuit 20 and the like are mounted may be located on the opposite side of the display surface (e.g., the rear side of the display device 1).

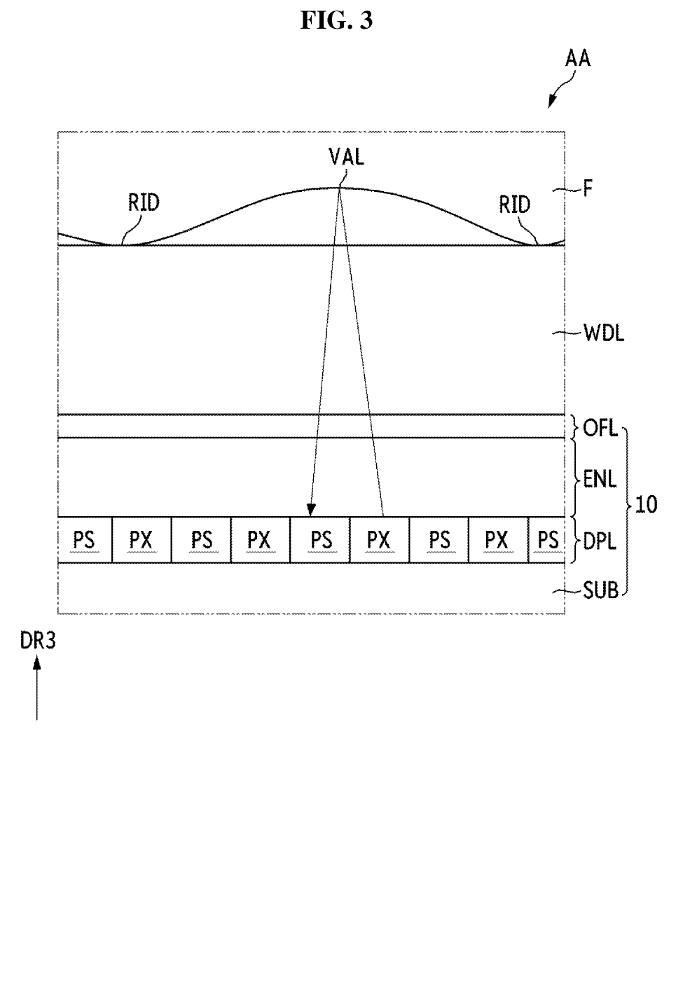

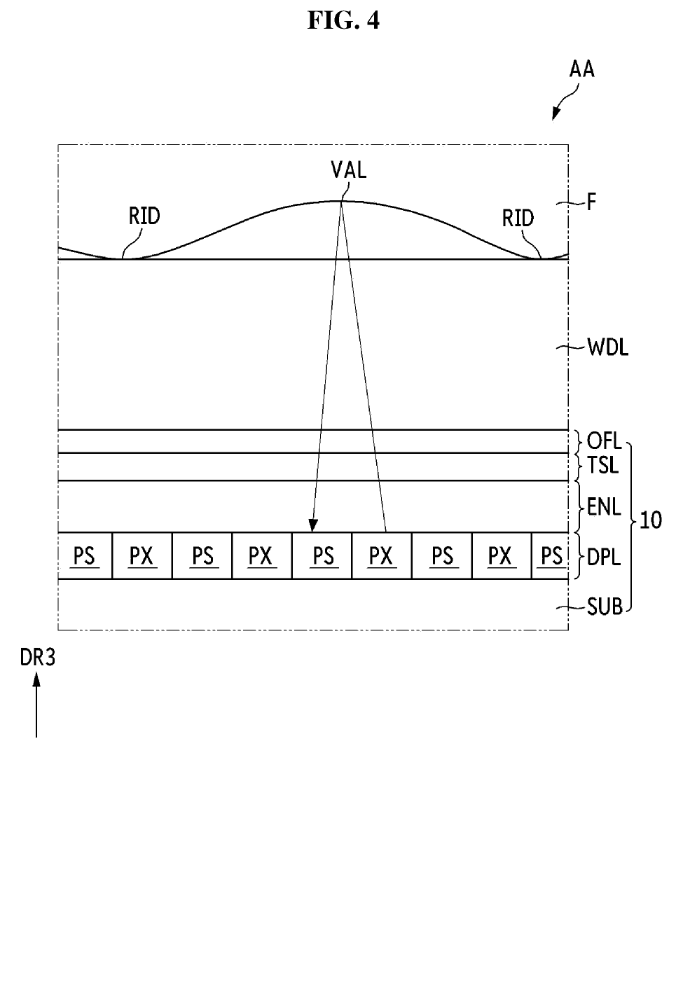

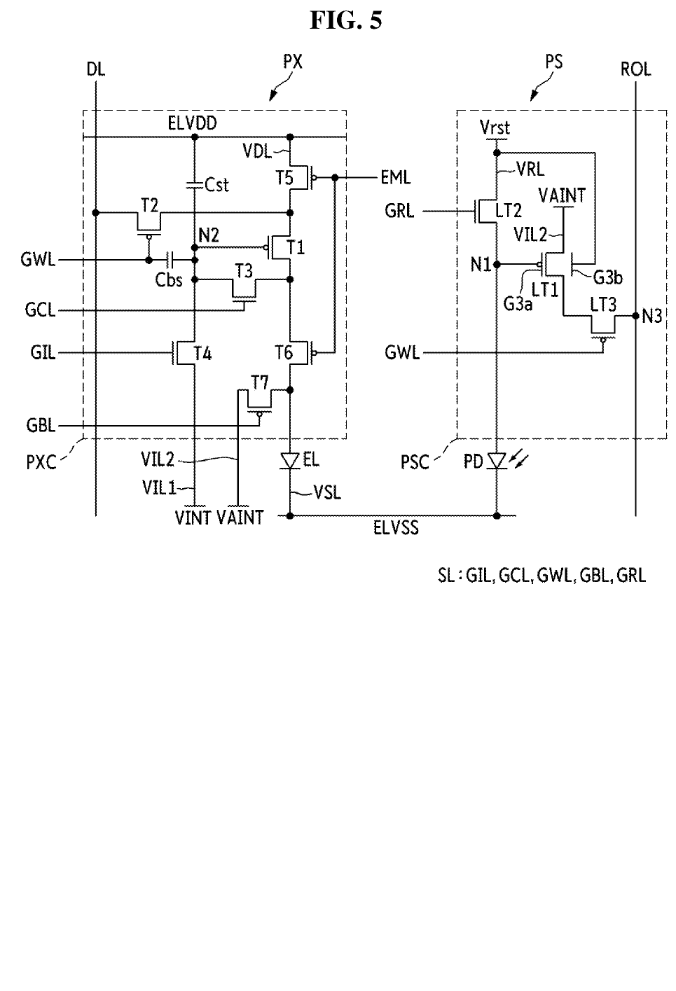

The active area AA may include a display area. For example, the active area AA may completely overlap with the display area. In the active area AA (or display area), pixels (e.g., pixels PX of FIGS. 3 or 4) for displaying images may be arranged. For example, the active area AA may include pixel areas where pixels are arranged or provided. Each of the pixel areas may include an emission area. According to an embodiment of the present disclosure, a light-emitting element (e.g., a light-emitting element EL of FIG. 5) may be arranged in each emission area.

The active area AA may further include a sensing area that reacts to light. For example, the active area AA may further include a sensing area (e.g., a light sensing area) that detects the amount or wavelength of incident light. According to the embodiment of the present disclosure, the sensing area may include a fingerprint sensing area that detects a user's fingerprint using photo sensors. For example, photo sensors (e.g., photo sensors PS of FIGS. 3 or 4) may be arranged in the active area AA. Each of the photo sensors may include a photoelectric conversion element (e.g., a photoelectric conversion element PD of FIG. 5). The photoelectric conversion element may detect incident light and convert it into an electrical signal.

For example, the active area AA may include photo sensors including the respective photoelectric conversion elements. The photo sensors may output detection signals corresponding to the incident light, and may detect a user input (e.g., a fingerprint input) provided to the active area AA using the detection signals.

According to an embodiment of the present disclosure, the sensing area may overlap with the display area. For example, the sensing area may be a part of the display area or may be substantially the same area as the display area. In this instance, the sensing area may be a part of the active area AA or may be the entire active area AA.

The non-active area NA may include a non-display area and may be located around the active area AA. The non-active area NA may be located on at least one side of the active area AA and may partially or entirely surround the active area AA. Lines, pads and/or driver circuit 20 electrically connected to pixels and/or photo sensors of the active area AA may be arranged in the non-active area NA.

The driver circuit 20 may be electrically connected to the pixels and the photo sensors in the active area AA, and may drive the pixels and the photo sensors. For example, the driver circuit 20 may generate driving signals and/or supply voltages for driving the pixels and the photo sensors, and may output the driving signals and/or the supply voltages to the respective pixels and the photo sensors. For example, the driver circuit 20 may include at least one of a gate driver circuit including a scan driver (or a part of the gate driver circuit), and a source driver circuit including a data driver (or a part of the source driver circuit).

The driver circuit 20 may be formed as an integrated circuit (IC) and mounted on the display panel 10 or on the circuit board 30 connected to the display panel 10. According to an embodiment of the present disclosure, the driver circuit 20 may be provided outside the active area AA. According to another embodiment, at least a part of the driver circuit 20 (e.g., at least a part of the scan driver) may be provided inside the active area AA and may be formed together with the pixels.

The circuit board 30 may be connected or attached to one end of the display panel 10. For example, the circuit board 30 may be attached to one end of the display panel 10 using an anisotropic conductive film (ACF). Lead lines of the circuit board 30 may be electrically connected to the pad areas of the display panel 10. According to the embodiment of the present disclosure, the circuit board 30 may be a flexible printed circuit board (FPCB), or a flexible film such as a chip-on-film (COF).

The read-out circuit 40 may be electrically connected to the photo sensors arranged in the active area AA. The read-out circuit 40 may receive an electrical signal associated with the electric current flowing to the photo sensors. The read-out circuit 40 may convert the electrical signal received from the photo sensors and transmit it to a processor (e.g., a processor provided in the display device 1 or a host device) connected to the read-out circuit 40, or may execute a given function based on the electrical signal.

According to the embodiment of the present disclosure, the read-out circuit 40 may be formed as an integrated circuit IC and may be attached on the circuit board 30 by using the chip-on-film (COF) technique, but embodiments are not limited thereto. For example, the read-out circuit 40 may be attached on the non-active area NA of the display panel 10 by chip-on-glass (COG) technique, chip-on-plastic (COP) technique, ultrasonic bonding, etc.

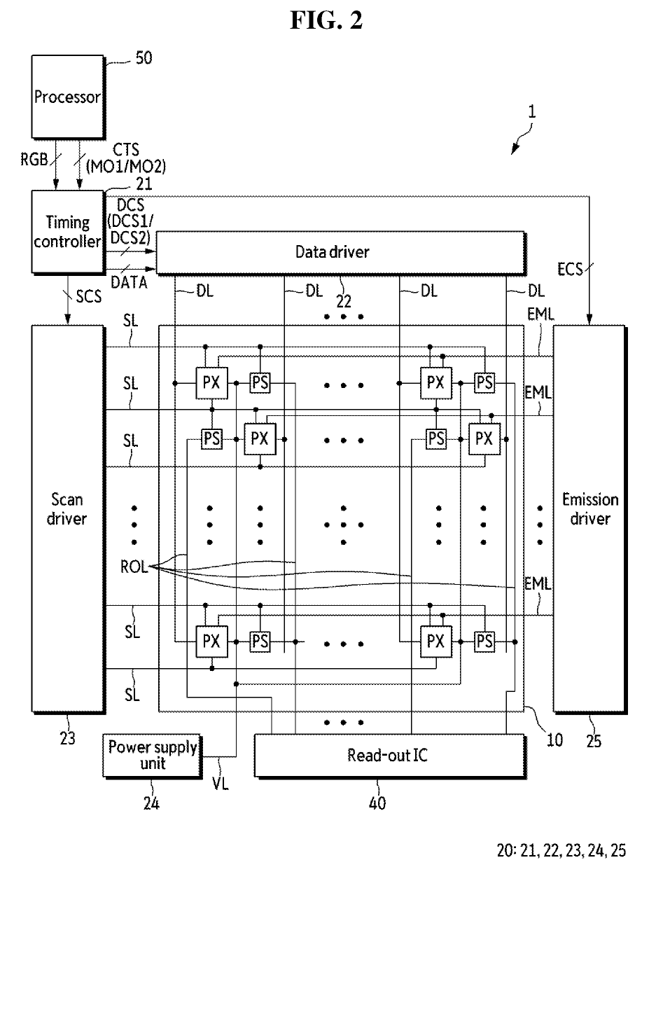

FIG. 2 is a block diagram of the display device 1 according to the embodiment of the present disclosure.

Referring to FIG. 2 in conjunction with FIG. 1, the display device 1 may include the display panel 10, the driver circuit 20, the read-out board 40 and the processor 50. Although the processor 50 is provided in the display device 1 according to the embodiment of FIG. 2, the present disclosure is not limited thereto. For example, the processor 50 may be provided in a host device connected to the display device 1.

The display panel 10 may include pixels PX and photo sensors PS arranged in the active area AA, scan lines SL and supply voltage lines VL connected (e.g., electrically connected) to the pixels PX and photo sensors PS, data lines DL and emission control lines EML connected to the pixels PX, and read-out lines ROL connected to the photo sensors PS.

Each of the pixels PX may be connected to at least one scan line SL, one data line DL, one emission control line EML, and at least one supply voltage line VL.

Each of the photo sensors PS may be connected to at least one scan line SL, one read-out line ROL, and at least one supply voltage line VL. According to the embodiment of the present disclosure, the photo sensors PS may be arranged between the pixels PX and may be formed inside the display panel 10 together with the pixels PX. For example, the photo sensors PS may be formed or arranged between the pixels PX located in the active area AA.

The scan lines SL may connect the pixels PX and the photo sensors PS to the scan driver 23. The scan lines SL may transmit or provide scan signals output from the scan driver 23 to the pixels PX and the photo sensors PS.

The data lines DL may connect the pixels PX to the data driver 22. The data lines DL may transmit or provide the data signals output from the data driver 22 to the pixels PX.

The emission control lines EML may connect the pixels PX to the emission control driver 25. The emission control lines EML may transmit or provide emission control signals output from the emission control driver 25 to the pixels PX.

The read-out lines ROL may connect the photo sensors PS to the read-out circuit 40. The read-out lines ROL may transmit or provide electrical signals (e.g., detection currents or detection signals) generated according to the light current output from the photo sensors PS to the read-out circuit 40. Accordingly, the read-out circuit 40 may detect a user input (e.g., fingerprint input).

The supply voltage lines VL may connect the pixels PX and the photo sensors PS to a power supply unit 24. For example, the supply voltage lines VL may transmit or provide to the pixels PX and the photo sensors PS a first supply voltage (e.g., a first supply voltage ELVDD of FIG. 5), a second supply voltage (e.g., a second supply voltage ELVSS of FIG. 5) and/or other supply voltages generated or output from the power supply unit 24. Although one supply voltage line VL is provided to the display panel 10 in the example shown in FIG. 2, more than one supply voltage lines VL may be provided or formed on the display panel 10 depending on the type and/or number of supply voltages required to drive the pixels PX and the photo sensors PS. The first supply voltage ELVDD may have the value of 2.8 V, and the second supply voltage ELVSS may have the value of -3.5 V.

The driver circuit 20 may include the data driver 22 that drives the pixels PX, the scan driver 23 that drives the pixels PX and the photo sensors PS, and a timing controller 21 that controls the driving timing of the data driver 22 and the scan driver 23. According to the embodiment of the present disclosure, the driver circuit 20 may further include the power supply unit 24 that generates and/or transmits supply voltages for driving the pixels PX and the photo sensors PS and/or the emission control driver 25 that drives the pixels PX.

The timing controller 21 may receive image signals RGB and control signals CTS from the processor 50. The timing controller 21 may output image data DATA, a data control signal DCS, a scan control signal SCS and an emission control signal ECS based on the image signals RGB and the control signals CTS. The image data DATA and the data control signal DCS may be provided to the data driver 22. The scan control signal SCS and the emission control signal ECS may be provided to the scan driver 23 and the emission control driver 25, respectively.

According to the embodiment of the present disclosure, the control signals CTS may include a first mode control signal MO1 and a second mode control signal MO2. The timing controller 21 may generate a first data control signal DCS1 when the first mode control signal MO1 is provided, and may generate a second data control signal DCS2 when the second mode control signal MO2 is provided.

The data driver 22 may generate data signals corresponding to the image data DATA and output the data signals to the data lines DL. For example, the data driver 22 may convert the image data DATA into analog data voltages and may output them to the data lines DL. The data signals may be provided to the pixels PX through the data lines DL.

The scan driver 23 may generate scan signals in response to the scan control signal SCS and may output the scan signals to the scan lines SL. The scan signals may be provided to the pixels PX and the photo sensors PS through the scan lines SL.

The power supply unit 24 may generate at least one supply voltage for driving the pixels PX and the photo sensors PS, and may output the at least one supply voltage to at least one supply voltage line VL. The at least one supply voltage may be provided to the pixels PX and the photo sensors PS through the supply voltage line VL.

The emission control driver 25 may generate the emission control signals in response to the emission control signal ECS and may output the emission control signals to the emission control lines EML. The emission control driver 25 may be formed or provided separately from the scan driver 23 or may be integrated with the scan driver 23.

The read-out circuit 40 may be connected to the photo sensors PS through the read-out lines ROL and may receive an electrical signal (e.g., a current flowing in each of the photo sensors PS) corresponding to the amount of light received by the photo sensors PS. The read-out circuit 40 may generate data corresponding to the magnitude of the electrical signal input from each of the photo sensors PS, e.g., digital detection data, and transmit it to the processor 50. When a user's fingerprint is detected using the electrical signal from the photo sensors PS, the processor 50 may analyze the digital detection data to determine whether or not the digital detection data matches a previously registered fingerprint of the user. If the previously registered fingerprint is identical to the digital detection data transmitted from the read-out circuit 40, the set functions may be performed.

The processor 50 may send image signals RGB and control signals CTS provided from the outside to the timing controller 21. The processor 50 may further include a graphics processing unit (hereinafter referred to as GPU) that provides graphics on the image signal RGB. The image signal RGB may be provided to the timing controller 21 as an image source which has been subjected to graphic processing in the GPU. The image signal RGB may have a certain frequency (e.g., the frequency of 120 Hz or the frequency of 30 Hz).

The control signals CTS output from the processor 50 may include a first mode control signal MO1, a second mode control signal MO2, a clock signal, an enable signal, etc. The first mode control signal MO1 may include a signal in a display mode for displaying a normal image. The second mode control signal MO2 may include a signal in a detection mode for detecting a user's fingerprint, etc. According to an embodiment of the present disclosure, the second mode control signal MO2 may be a signal for causing at least some pixels PX (e.g., green pixels) to emit light while the detection mode is executed. Accordingly, the pixels PX may be used as a light source to detect a user's fingerprint, etc.

The processor 50 may provide the first mode control signal MO1 to the timing controller 21 to display images on the display panel 10. The processor 50 may provide the second mode control signal MO2 to the timing controller 21 to detect a user's fingerprint, etc. The timing controller 21 may drive the pixels PX of the display panel 10 in response to the first mode control signal MO1. The timing controller 21 may drive the pixels PX and the photo sensors PS of the display panel 10 in response to the second mode control signal MO2.

FIG. 3 is a cross-sectional view of the active area AA of the display device 1 according to the embodiment for illustrating a method for detecting the fingerprint of a finger F. For example, FIG. 3 shows a method for detecting a fingerprint of the finger F located on the active area AA of the display device 1.

Referring to FIG. 3 in conjunction with FIGS. 1 and 2, the display device 1 may include the display panel 10 and a window WDL arranged on the display panel 10. The display panel 10 may include a substrate SUB, a display layer DPL placed on the substrate SUB, an encapsulation layer ENL placed on the display layer DPL, and an optical filter layer OFL.

The substrate SUB may be a base member for forming or arranging components of the display panel 10. The substrate SUB may include the active area AA and the non-active area NA. For example, a portion of the substrate SUB may be defined as the active area AA, whereas the remaining portion of the substrate SUB may be defined as the non-active area NA.

The display layer DPL may include the pixels PX and the photo sensors PS arranged on the substrate SUB. The pixels PX and the photo sensors PS may be arranged and/or formed on the substrate SUB such that they are located in the active area AA.

Although the pixels PX and the photo sensors PS are alternately arranged in at least one direction (e.g., the first direction DR1 and/or the second direction DR2 intersecting the third direction DR3 in the example shown in FIG. 3) for convenience of illustration, the arrangement, number, and/or resolution of the pixels PX and the photo sensors PS may be variously changed depending on the embodiments.

According to an embodiment of the present disclosure, the pixels PX and the photo sensors PS may be formed simultaneously. For example, after the pixel circuit of each of the pixels PX (e.g., the pixel circuit PXC of FIG. 5) and the photo sensor circuit of each of the photo sensors PS (e.g., the photo sensor circuit PSC of FIG. 5) have been formed on the substrate SUB simultaneously, the light-emitting element of each of the pixels PX (e.g., the light-emitting element EL of FIG. 5) and the photoelectric conversion element of each of the photo sensors PS (e.g., the photoelectric conversion element PD of FIG. 5) (or at least a portion of the light-emitting element and at least a portion of the photoelectric conversion element) may be simultaneously formed on the substrate SUB on which the pixel circuit and the photo sensor circuit are formed.

The display device 1 in which photo sensors PS are arranged or formed inside the display panel 10 together with the pixels PX as in the embodiment of FIG. 2 can have a reduced thickness compared to a display device according to Comparative Example in which photo sensors are arranged on a separate layer and attached to a surface of the display panel. In addition, the display device 1 according to the embodiment can increase the amount of light received by the photo sensors PS compared to the display device according to Comparative Example.

The encapsulation layer ENL may be arranged and/or formed on the display layer DPL to cover at least the pixels PX and the photo sensors PS. The encapsulation layer ENL can protect the pixels PX and the photo sensors PS.

The optical filter layer OFL may be located above the pixels PX and the photo sensors PS. For example, the optical filter layer OFL may be located on the encapsulation layer ENL.

The window WDL may be placed on the display panel 10 to protect the display panel 10. For example, the window WDL may be provided on a display surface of the display panel 10.

A user’s fingerprint includes ridges RID and valleys VAL. When a user's finger F (e.g., a part of the finger F including a fingerprint area) comes into contact with (or is in close proximity to) the upper surface of the window WDL, light emitted from the pixels PX of the display panel 10 may be reflected from ridges RID of the finger F and valleys VAL between the ridges RID, as indicated by the arrow in FIG. 3. The ridges RID of the finger F may be in contact with the upper surface of the window WDL, whereas the valleys VAL of the finger F may not be in contact with the window WDL. Accordingly, the upper surface of the window WDL may be in contact with air at the valleys VAL of the finger F.

Since the refractive index of the finger F is different from the refractive index of the air, the amount of light reflected off the ridges RID may be different from the amount of light reflected from the valleys VAL. Accordingly, the shape of the fingerprint formed on the finger F can be derived based on the difference between the amounts of light received by the photo sensors PS for the lights reflected off the finger F. For example, each of the photo sensors PS may output an electrical signal corresponding to the amount of light received, and the shape of the fingerprint formed on the finger F may be detected or identified using the electrical signals output from the photo sensors PS.

FIG. 4 is a cross-sectional view of the active area AA of the display device 1 according to the embodiment for illustrating a method for detecting the fingerprint of a finger F.

Referring to FIG. 4 in conjunction with FIGS. 1-3, the display device 1 may further include a touch sensor layer TSL. According to an embodiment of the present disclosure, the touch sensor layer TSL may be provided and/or formed in the display panel 10. For example, the touch sensor layer TSL may be arranged between the encapsulation layer ENL and the optical filter layer OFL, and may be formed directly on the encapsulation layer ENL. The position of the touch sensor layer TSL may vary depending on the embodiments.

The touch sensor layer TSL may include sensing patterns for detecting a user's touch input (e.g., touch electrodes for generating an electrical signal according to a touch input) and an overcoat layer covering the sensing patterns. The type, structure, material, etc., of the sensing patterns arranged on the touch sensor layer TSL may vary depending on the embodiments.

The display device 1 may detect a user's touch input provided on the display surface side (e.g., the upper surface of the window WDL) by using the touch sensor layer TSL. The other elements of the display device 1 according to the embodiment of FIG. 4 and a method for detecting a fingerprint of a finger F by using the photo sensors PS are substantially similar or identical to those of the display device 1 according to the embodiment of FIG. 3; and, therefore, any redundant descriptions will be omitted.

FIG. 5 is a circuit diagram of a pixel PX and a photo sensor PS according to an embodiment.

According to the embodiment disclosed in FIG. 5, scan lines SL connected to the pixels PX include a scan initialization line GIL, a scan control line GCL, a scan write line GWL, and a scan bias line GBL. According to the embodiment of the present disclosure, the scan lines SL may further include a scan reset line GRL connected to at least one photo sensor PS.

According to an embodiment of the present disclosure, the scan reset line GRL may be integrated with one of the scan initialization line GIL, the scan control line GCL and the scan bias line GBL, or may be separated from the scan initialization line GIL, the scan control line GCL and the scan bias line GBL to receive a separate reset signal. According to an embodiment of the present disclosure, the reset signal may be applied either sequentially to the photo sensors PS sorted into rows or blocks at least, or simultaneously to the photo sensors PS arranged in the active area AA. For example, the photo sensors PS may be reset sequentially or simultaneously.

According to the embodiment of the present disclosure, the photo sensor PS may be driven by using at least one of the scan signals for driving the pixel PX. For example, the photo sensor PS may be driven by using the first scan signal transmitted on the scan write line GWL.

Referring to FIG. 5 in conjunction with FIGS. 1 and 4, the pixel PX may include a light-emitting element EL and a pixel circuit PXC (or a pixel driver) connected to the light-emitting element EL.

The light-emitting element EL is the light source of the pixel PX and may emit light in response to a driving current provided from the pixel circuit PXC. As the driving current increases, the light-emitting element EL may emit light with higher luminance.

According to the embodiment of the present disclosure, the light-emitting element EL may be, but is not limited to, an organic light-emitting diode. For example, the light-emitting element EL may be an inorganic light-emitting element, a quantum-dot light-emitting element, or other types of light-emitting element.

The pixel circuit PXC may control the emission timing and luminance of the light-emitting element EL by controlling the driving current supplied to the light-emitting element EL. The pixel circuit PXC may include a driving transistor, a switching transistor, and a capacitor Cst. According to the embodiment of the present disclosure, the driving transistor may include a first transistor, and the switching transistor may include second to seventh transistors T2, T3, T4, T5, T6 and T7.

The first transistor T1 may include a gate electrode, a first electrode, and a second electrode. One of the first electrode and the second electrode of the first transistor T1 may be a source electrode, and the other may be a drain electrode. The first transistor T1 may control a source-drain current (hereinafter referred to as driving current) flowing between the first electrode and the second electrode in response to a voltage of a data signal applied to the gate electrode.

The second transistor T2 may include a gate electrode connected to the scan write line GWL, a first electrode connected to the data line DL, and a second electrode connected to the first electrode of the first transistor T1. One of the first electrode and the second electrode of the second transistor T2 may be a source electrode, and the other may be a drain electrode. The second transistor T2 may be turned on by a first scan signal provided to the scan write line GWL to connect the first electrode of the first transistor T1 with the data line DL. When the second transistor T2 is turned on, the voltage of the data signal provided to the data line DL may be applied to the first electrode of the first transistor T1.

The third transistor T3 may include a gate electrode connected to the scan control line GCL, a first electrode connected to the second electrode of the first transistor T1, and a second electrode connected to the gate electrode of the first transistor T1 (or the second node N2). One of the first electrode and the second electrode of the third transistor T3 may be a source electrode, and the other may be a drain electrode. The third transistor T3 may be turned on by a scan control signal provided to the scan control line GCL to connect the gate electrode of the first transistor T1 with the second electrode. When the third transistor T3 is turned on, the first transistor T1 may behave as a diode.

The fourth transistor T4 may include a gate electrode connected to the scan initialization line GIL, a first electrode connected to the gate electrode of the first transistor T1, and a second electrode connected to the first initialization voltage line VIL1. One of the first electrode and the second electrode of the fourth transistor T4 may be a source electrode, and the other may be a drain electrode. The fourth transistor T4 may be turned on by a scan initialization signal provided to the scan initialization line GIL to connect the gate electrode of the first transistor T1 with the first initialization voltage line VIL1. When the fourth transistor T4 is turned on, a first initialization voltage VINT of the first initialization voltage line VIL1 may be applied to the gate electrode of the first transistor T1. The first initialization voltage VINT may have the value of -2.3 V.

The fifth transistor T5 may include a gate electrode connected to an emission control line EML, a first electrode connected to the first supply voltage VDL, and a second electrode connected to the first electrode of the first transistor T1. One of the first electrode and the second electrode of the fifth transistor T5 may be a source electrode, and the other may be a drain electrode. The fifth transistor T5 may be turned on by an emission control signal provided to the emission control line EML to connect the first electrode of the first transistor T1 with the first supply voltage line VDL from which a first supply voltage ELVDD is applied. When the fifth transistor T5 is turned on, the first supply voltage ELVDD may be applied to the first electrode of the first transistor T1.

The sixth pixel transistor T6 may include a gate electrode connected to the emission control line EML, a first electrode connected to the second electrode of the first transistor T1, and a second electrode connected to the light-emitting element EL. One of the first electrode and the second electrode of the sixth transistor T6 may be a source electrode, and the other may be a drain electrode. The sixth transistor T6 may be turned on by the emission control signal provided on the emission control line EML to connect the first transistor T1 with the light-emitting element EL. When both the fifth and sixth transistors T5 and T6 are turned on, a driving current having the magnitude proportional to the voltage of the gate electrode of the first transistor T1 may flow through the light-emitting element EL.

The seventh transistor T7 may include a gate electrode connected to the scan bias line GBL, a first electrode connected to an anode electrode of the light-emitting element EL, and a second electrode connected to the second initialization voltage line VIL2. One of the first electrode and the second electrode of the seventh transistor T7 may be a source electrode, and the other may be a drain electrode. The seventh transistor T7 may be turned on by a (1_1) scan signal provided to the scan bias line GBL to connect the anode electrode of the light-emitting element EL with the second initialization voltage line VIL2. When the seventh transistor T7 is turned on, a second initialization voltage VAINT of the second initialization voltage line VIL2 may be applied to the anode electrode of the light-emitting element EL. The second initialization voltage VAINT may have the same value as the second supply voltage ELVSS. For example, the second initialization voltage VAINT may have the value of -3.5 V. On the other hand, the cathode electrode of the light-emitting element EL may be connected to a second supply voltage line VSL. The second supply voltage line VSL may transmit the second supply voltage ELVSS described above.

The first capacitor Cst may be connected between the gate electrode of the first transistor T1 and the first supply voltage line VDL. The first capacitor Cst may store a voltage corresponding to the voltage of the data signal applied to the gate electrode of the first transistor T1.

A second capacitor Cbs may be connected between the gate electrode of the first transistor T1 and the gate electrode of the second transistor T2 (or the scan write line GWL). The second capacitor Cbs may store a voltage corresponding to the voltage of the data signal applied to the gate electrode of the first transistor T1.

According to the embodiment of the present disclosure, the active layer (e.g., a semiconductor pattern including a channel region) of each of the first to seventh transistors T1, T2, T3, T4, T5, T6 and T7 may be formed of one of polysilicon, amorphous silicon, and oxide semiconductor. For example, the active layer of each of the first transistor T1, the second transistor T2, and the fifth to seventh transistors T5, T6 and T7 may be made of polysilicon. The active layer of each of the third transistor T3 and the fourth transistor T4 may be formed of oxide semiconductor. In this instance, the first transistor T1, the second transistor T2 and the fifth to seventh transistors T5, T6 and T7 may be implemented as p-type transistors, while the third transistor T3 and the fourth transistor T4 may be implemented as n-type transistors.

The photo sensor PS may include a photoelectric conversion element PD (or light sensing element) and a photo sensor circuit PSC (or sensor driver) that controls a detection current according to the photocurrent of the photoelectric conversion element PD.

The photoelectric conversion element PD may convert incident light from the outside into an electrical signal. According to the embodiment of the present disclosure, the photoelectric conversion element PD may be a photo diode including an anode electrode, a cathode electrode, and a photoelectric conversion layer located between the anode electrode and the cathode electrode. According to an embodiment of the present disclosure, the photoelectric conversion element PD may be an inorganic photodiode made of an inorganic material such as a PN photodiode and a PIN photodiode, or a phototransistor. Alternatively, the photoelectric conversion element PD may be an organic photodiode including an electron donating material that generates donor ions and an electron accepting material that generates acceptor ions.

The photoelectric conversion element PD may generate photocharges when they are exposed to external light. The generated photocharges may be accumulated in the anode electrode of each of the photoelectric conversion elements PD. In this instance, the voltage of the first node N1 electrically connected to the anode electrode of the photoelectric conversion element PD may increase. When the first and third sensor transistors LT1 and LT3 are turned on and accordingly the photoelectric conversion element PD and the read-out line ROL are connected with each other, a detection voltage may be accumulated at a third node N3 between the read-out line ROL and the third sensor transistor LT3 in proportion to the voltage of the first node N1 where the charges are accumulated. The sensing voltage may have the value of 1 V, for example.

The photo sensor circuit PSC may include sensor transistors for controlling a sensing current generated from the photoelectric conversion element PD. For example, the photo sensor circuit PSC may include first to third sensor transistors LT1, LT2 and LT3.

The first sensor transistor LT1 may include a gate electrode (e.g., a top gate electrode; G3a) connected to the first node N1, a counter gate electrode (e.g., a bottom gate electrode; G3b) connected to a reset voltage line VRL, a first electrode connected to the second initialization voltage line VIL2, and a second electrode connected to the first electrode of the third sensor transistor LT3. For example, the first sensor transistor LT1 may be a double gate transistor including two gate electrodes G3a and G3b. One of the first electrode and the second electrode of the first sensor transistor LT1 may be a source electrode, and the other may be a drain electrode. The first sensor transistor LT1 may be turned on by the voltage at the first node N1 to connect the second initialization voltage line VIL2 with the first electrode of the third sensor transistor LT3. The first sensor transistor LT1 may be a source follower amplifier that generates a source-drain current proportional to the amount of charges at the first node N1 input to the gate electrode. Although the first electrode of the first sensor transistor LT1 is connected to the second initialization voltage line VIL2 according to the embodiment of FIG. 5, the embodiments are not limited thereto. For example, the first electrode of the first sensor transistor LT1 may be connected to the first supply voltage line VDL or the first initialization voltage line VIL1.

The second sensor transistor LT2 may include a gate electrode connected to the scan reset line GRL, a first electrode connected to the reset voltage line VRL, and a second electrode connected to the first node N1. One of the first electrode and the second electrode of the second sensor transistor LT2 may be a source electrode, and the other may be a drain electrode. The second sensor transistor LT2 may be turned on by a reset control signal provided to the scan reset line GRL, and may connect the reset voltage line VRL that applies the reset voltage Vrst to the first node N1. When the second sensor transistor LT2 is turned on, the voltage of the first node N1 may be initialized by the reset voltage Vrst.

The third sensor transistor LT3 may include a gate electrode connected to the scan write line GWL, a first electrode connected to the second electrode of the first sensor transistor LT1, and a second electrode connected to the read-out line ROL. One of the first electrode and the second electrode of the third sensor transistor LT3 may be a source electrode, and the other may be a drain electrode. The third sensor transistor LT3 may be turned on by a first scan signal provided to the scan write line GWL to connect the second electrode of the first sensor transistor LT1 with the read-out line ROL. When the third sensor transistor LT3 is turned on, an electrical signal corresponding to the photocurrent flowing to the photo sensor PS through the read-out line ROL may be transmitted to the read-out circuit 40.

According to an embodiment of the present disclosure, the active layer of each of the first to third sensor transistors LT1, LT2 and LT3 may be formed of one of poly silicon, amorphous silicon, and oxide semiconductor. For example, the active layer of each of the first sensor transistor LT1 and the third sensor transistor LT3 may be formed of polysilicon, while the active layer of the second sensor transistor LT2 may be formed of oxide semiconductor. In this instance, the first sensor transistor LT1 and the third sensor transistor LT3 may be implemented as p-type transistors, and the second sensor transistor LT2 may be implemented as an n-type transistor.

According to the embodiment, the first sensor transistor LT1 may include two gate electrodes G3a and G3b. For example, the first sensor transistor LT1 may include a gate electrode G3a and a counter gate electrode G3b facing each other with a channel region of an active layer between the gate electrodes.

A negative voltage having the largest absolute value among the supply voltages ELVDD, ELVSS, VINT, VAINT and Vrst provided to the pixel PX and the photo sensor PS may be applied to the counter gate electrode G3b of the first sensor transistor LT1. For example, among the supply voltages ELVDD, ELVSS, VINT, VAINT and Vrst, the reset voltage Vrst may have the largest voltage in the negative direction, and this reset voltage Vrst may be applied to the counter gate electrode G3b. The reset voltage Vrst may have a value lower than the second supply voltage ELVSS. For example, when the second supply voltage ELVSS is - 3.5 V, the reset voltage Vrst may be - 6.1 V.

When the first sensor transistor LT1 operates (e.g., is turned on), the voltage difference between the gate electrode G3a and the source electrode of the first sensor transistor LT1 (hereinafter referred to as a first gate-source voltage) and the voltage difference between the counter gate electrode G3b and the source electrode of the first sensor transistor LT1 (hereinafter referred to as a second gate-source voltage) may each be - 7.1 V. For example, the first gate-source voltage of the first sensor transistor LT1 may be a voltage obtained by subtracting the voltage of the read-out line ROL of 1 V (e.g., the detection voltage of 1 V) from the reset voltage Vrst of -6.1 V, and the second gate-source voltage of the first sensor transistor LT1 may also be a voltage obtained by subtracting the voltage of the read-out line ROL of 1 V (e.g., the detection voltage of 1 V) from the reset voltage Vrst of -6.1 V.

According to the embodiment, the threshold voltage of the first sensor transistor LT1 may be further shifted in the positive direction due to the voltage applied to the counter gate electrode G3b of that first sensor transistor LT1. For example, Compared to the threshold voltage of the first sensor transistor LT1 including only the gate electrode G3a among the two gate electrodes G3a and G3b, the threshold voltage of the first sensor transistor LT1 including both the two gate electrodes G3a and G3b may be shifted further in the positive direction.

As the threshold voltage of the first sensor transistor LT1 described above is located further in the positive direction, the amount of current of the first sensor transistor LT1 may increase, which may mean that the sensing capability of the first sensor transistor LT1 is improved. By doing so, the signal-to-noise ratio (SNR) of the first sensor transistor LT1 can be improved.

Typically, since the driving transistor of the pixel PX (e.g., the first transistor T1) and the driving transistor of the photo sensor PS (e.g., the first sensor transistor LT1) are fabricated via the same process, it is difficult to independently control the threshold voltage of the first transistor T1 and the threshold voltage of the first sensor transistor LT1. In contrast, according to the embodiment, since the first sensor transistor LT1 is fabricated to include two gate electrodes G3a and G3b, the threshold voltage of the first sensor transistor LT1 can be formed to move further in the positive direction without affecting the threshold voltage of the first transistor T1. Accordingly, the threshold voltage of the first sensor transistor LT1 may have a value further moved in the positive direction than the threshold voltage of the first transistor T1. Accordingly, the threshold voltage of the first sensor transistor LT1 may have a larger value in the positive direction than the threshold voltage of the first transistor T1.

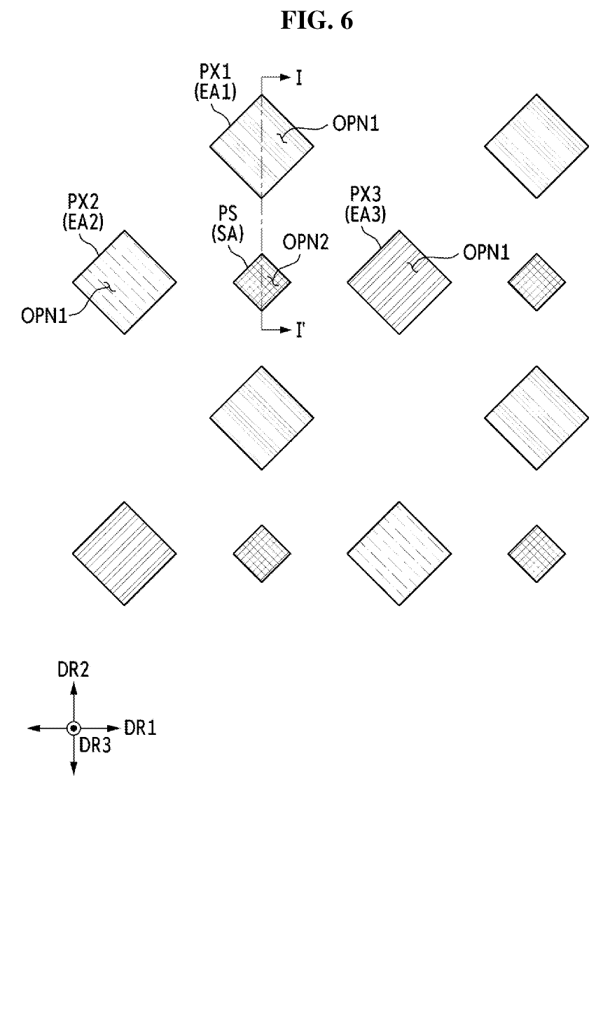

FIG. 6 is a plan view showing the layout of pixels PX and photo sensors PS according to an embodiment.

Referring to FIG. 6 in conjunction with FIGS. 1-5, the pixels PX may include first color pixels (also referred to as first pixels PX1) that emit light of a first color, second color pixels (also referred to as second pixels PX2) that emit light of a second color, and third color pixels (also referred to as third pixels PX3) that emit light of a third color. According to an embodiment of the present disclosure, the first color pixels PX1 may be green pixels that emit green light, the second color pixels PX2 may be red pixels that emit red light, and the third color pixels PX3 may be blue pixels that emit blue light. It should be understood, however, that the embodiments of the present disclosure are not limited thereto. The type, configuration and color of light emitted by each pixel PX may vary depending on the embodiments.

According to the embodiment of the present disclosure, at least one first color pixel PX1, at least one second color pixel PX2 and at least one third color pixel PX3 adjacent to each other may form a unit pixel.

According to the embodiment of the present disclosure, photo sensors PS may be arranged between adjacent pixels. For example, a photo sensor may be located among four adjacent pixels. According to the embodiment of the present disclosure, the sensing area SA of each of the photo sensors PS may be adjacent to at least one first emission area EA1, and each of the photo sensors PS may generate a detection signal using light emitted from the first emission area EA1. For example, each photo sensor PS may be arranged between the first emission areas EA1 of at least two first color pixels PX1 arranged in the pixel column in which that photo sensor PS is located, and may operate using the adjacent first color pixels PX1 as the light source. The shape, arrangement structure, and resolution of the pixels PX and the photo sensors PS are not limited to the embodiments shown in FIGS. 6-8, and may be varied in various ways depending on the embodiments.

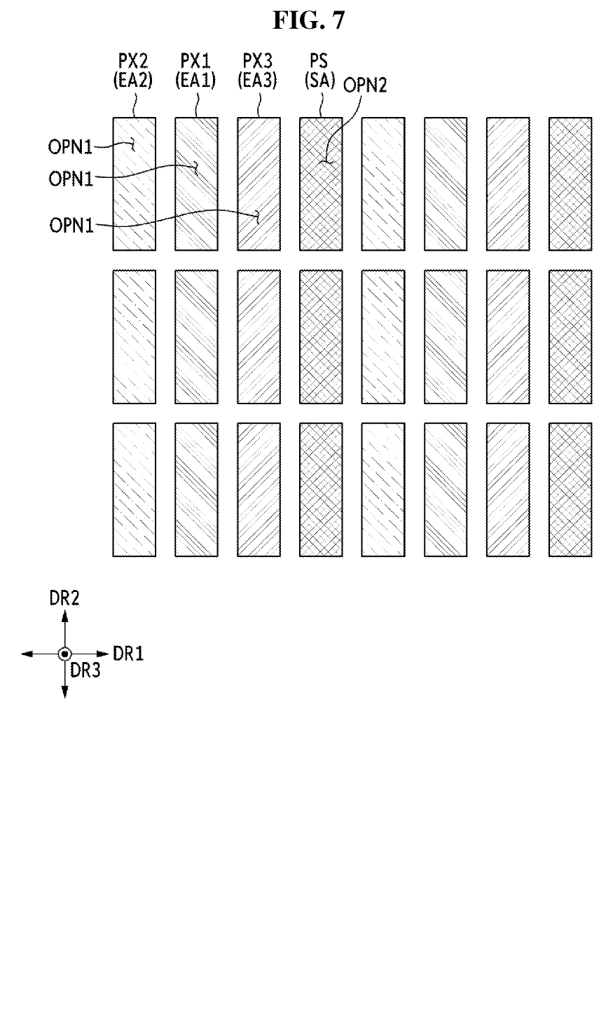

FIG. 7 is a plan view showing the layout of pixels PX and photo sensors PS according to another embodiment.

As shown in FIG. 7, first color pixels PX1, second color pixels PX2, third color pixels PX3 and photo sensors PS may be rectangular stripes arranged in a matrix configuration.

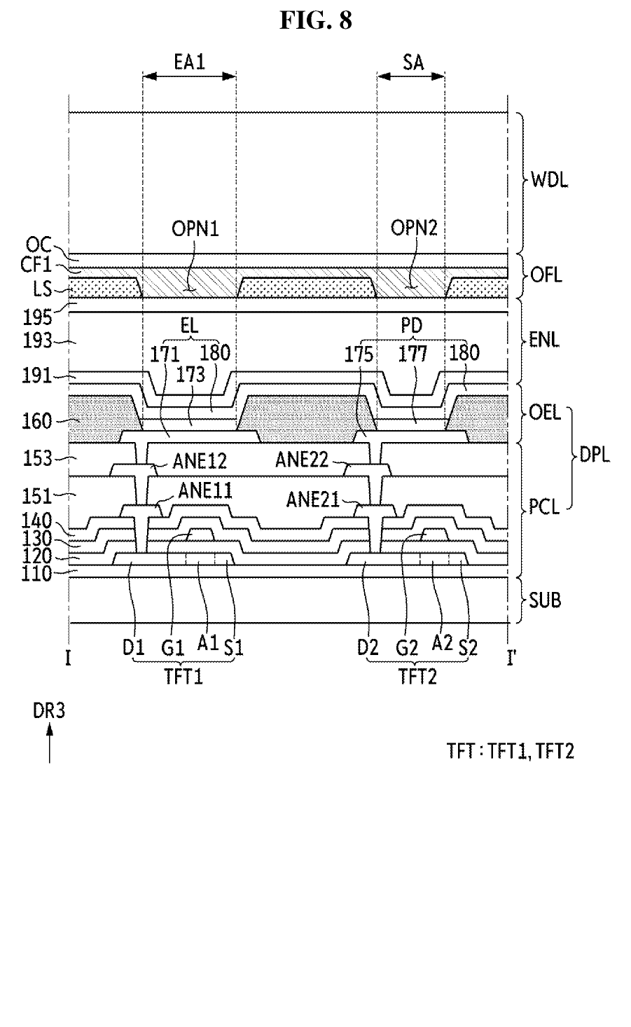

FIG. 8 is a cross-sectional view showing an example of the cross-section of the display device 1 taken along line I – I' of FIG. 6.

Referring to FIG. 8, the substrate SUB may be a base member (or base layer) of the display panel 10 and may be rigid or flexible. According to the embodiment, the substrate SUB may be, but is not limited to, one of a glass substrate, a quartz substrate, a glass ceramic substrate, a film substrate including a polymeric organic material, and a plastic substrate.

An active area AA and a non-active area NA may be defined on the substrate SUB. Pixels PX and photo sensors PS may be located in the active area AA on the substrate SUB. For example, the active area AA may include pixel areas including the respective emission areas EA, and photo sensor areas including the respective sensing areas SA.

The panel circuit layer PCL (e.g., a pixel circuit layer or a thin-film transistor layer) may be placed on the substrate SUB. The panel circuit layer PCL may include a barrier layer 110 (or a buffer layer) and circuit elements and/or lines arranged on the barrier layer 110. For example, the panel circuit layer PCL may include a first thin-film transistor TFT1 (also referred to as a pixel transistor) provided for each pixel PX, and a second thin-film transistor TFT2 (also referred to as a sensor transistor) provided for each photo sensor PS. For example, the first thin-film transistor TFT1 may be one of the first to seventh transistors T1 to T7 of FIG. 5, and the second thin-film transistor TFT2 may be one of the first to third sensor transistors LT1 to LT3 of FIG. 5. For example, the second thin-film transistor TFT2 may be the second sensor transistor LT2 of FIG. 5. The panel circuit layer PCL may further include the other circuit elements included in each pixel circuit PXC (e.g., other transistors, the first capacitor Cst, the second capacitor Cbs), the other circuit elements included in each photo sensor circuit PSC (e.g., other sensor transistors), and the lines connected to the pixels PX and the photo sensors PS.

The barrier layer 110 may be placed on the substrate SUB. The barrier layer 110 may include an inorganic insulating material including silicon nitride, silicon oxide or silicon oxynitride, or other insulating materials.

An active layer (or semiconductor pattern) of each of the thin-film transistors TFT may be arranged on the barrier layer 110. The active layer may include polycrystalline silicon, single crystal silicon, low-temperature polycrystalline silicon, amorphous silicon, oxide semiconductor, or other semiconductor materials.

The active layer of the first thin-film transistor TFT1 may include a first channel region A1, and a first source region S1 and a first drain region D1 doped with impurities to have conductivity. The first channel region A1 may overlap with the first gate electrode G1 in the third direction DR3 that is the thickness direction of the substrate SUB. The first source region S1 and the first drain region D1 may not overlap with the first gate electrode G1.

The active layer of the second thin-film transistor TFT2 may include a second channel region A2, and a second source region S2 and a second drain region D2 doped with impurities to have conductivity. The second channel region A2 may overlap with the second gate electrode G2 in the third direction DR3 that is the thickness direction of the substrate SUB. The second source region S2 and the second drain region D2 may not overlap with the second gate electrode G2.

According to the embodiment of the present disclosure, the first and second thin-film transistors TFT1 and TFT2 may be arranged in substantially the same layer on the substrate SUB. In addition, at least some of the elements of the first thin-film transistor TFT1 and at least some of the elements of the second thin-film transistor TFT2 may be formed together via the same process. Accordingly, the thickness of the display device 1 including the pixels PX and the photo sensors PS can be reduced or minimized, and the fabrication process of the display device 1 can become more efficient and/or simpler.

A first insulating layer 120 (e.g., a gate insulator) may be arranged on the active layers of the thin-film transistors TFT. According to the embodiment, the first insulating layer 120 may include at least one inorganic insulating layer including an inorganic insulating material.

The gate electrodes of each of the thin-film transistors TFT may be arranged on the first insulating layer 120. For example, the first gate electrode G1 of the first thin-film transistor TFT1 and the second gate electrode G2 of the second thin-film transistor TFT2 may be arranged on the first insulating layer 120. According to an embodiment of the present disclosure, the gate electrodes may include one of molybdenum (Mo), aluminum (Al), chromium (Cr), gold (Au), titanium (Ti), nickel (Ni), neodymium (Nd) and copper (Cu), or an alloy thereof. The gate electrodes may include other conductive materials. According to the embodiment of the present disclosure, the first electrode of the first capacitor Cst of FIG. 5 and/or at least one line, etc., may be further arranged on the first insulating layer 120.

A second insulating layer 130 (e.g., a first interlayer dielectric layer) may be placed on the gate electrodes of the thin-film transistors TFT. According to the embodiment, the second insulating layer 130 may include at least one inorganic insulating layer including an inorganic insulating material. According to the embodiment of the present disclosure, the second electrode of the first capacitor Cst of FIG. 5 and/or at least one line, etc., may be further arranged on the second insulating layer 130.

A third insulating layer 140 (e.g., a second interlayer dielectric layer) may be arranged on the second insulating layer 130, the second electrode of the first capacitor Cst and/or at least one line. According to the embodiment, the third insulating layer 140 may include at least one inorganic insulating layer including an inorganic insulating material. According to another embodiment, the second electrode of the first capacitor Cst may be arranged in the same layer as first anode connection electrodes ANE11 and ANE21, and the third insulating layer 140 may be eliminated.

The first anode connection electrodes ANE11 and ANE21 (or first bridge patterns) may be arranged on the third insulating layer 140. The first anode connection electrodes ANE11 and ANE21 may be connected to the drain regions D1 and D2 of the respective thin-film transistors TFT through respective contact holes penetrating the first insulating layer 120, the second insulating layer 130 and the third insulating layer 140. Although the first anode connection electrodes ANE11 and ANE21 are connected to the first drain region D1 and the second drain region D2, respectively, according to the embodiment of FIG. 8, the embodiments of the present disclosure are not limited thereto. For example, depending on the conductivity type (e.g., n-type or p-type) of each of the first thin-film transistor TFT1 and the second thin-film transistor TFT2, each of the first anode connection electrodes ANE11 and ANE21 may be connected to one of the first source region S1 and the first drain region D1, or one of the second source region S2 and the second drain region D2. According to the embodiment, the first anode connection electrodes ANE11 and ANE21 may include one of molybdenum (Mo), aluminum (Al), chromium (Cr), gold (Au), titanium (Ti), nickel (Ni), neodymium (Nd) and copper (Cu), or an alloy thereof.

A fourth insulating layer 151 (e.g., a first planarization film) may be located on the first anode connection electrodes ANE11 and ANE21. According to the embodiment of the present disclosure, the fourth insulating layer 151 may include an organic insulating layer of at least one layer containing an acrylic resin, an epoxy resin, a phenolic resin, a polyamide resin, a polyimide resin, or other organic insulating materials. The fourth insulating layer 151 may provide a flat surface over the thin-film transistors TFT having different heights.

The second anode connection electrodes ANE12 and ANE22 (or second bridge patterns) may be arranged on the fourth insulating layer 151. The second anode connection electrodes ANE12 and ANE22 may be connected to the first anode connection electrodes ANE11 and ANE21, respectively, through contact holes that extend through the fourth insulating layer 151. According to an embodiment of the present disclosure, the second anode connection electrodes ANE12 and ANE22 may include the same material as the first anode connection electrodes ANE11 and ANE21.

A fifth insulating layer 153 (e.g., a second planarization film) may be located on the second anode connection electrodes ANE12 and ANE22. According to an embodiment of the present disclosure, the fifth insulating layer 153 may include the same material as the fourth insulating layer 151. According to an embodiment of the present disclosure, the second anode connection electrodes ANE12 and ANE22 and/or the fifth insulating layer 153 may be eliminated. For example, the first anode connection electrodes ANE11 and ANE21 may be directly connected to the respective light-emitting elements EL and photoelectric conversion elements PD.

An optical element layer OEL may be placed on the fifth insulating layer 153. The optical element layer OEL may include the light-emitting element EL of each pixel PX, the photoelectric conversion element PD of each photo sensor PS, and a bank 160. The light-emitting elements EL may be located in the respective emission areas EA (e.g., the emission area EA of that pixel PX), and the photoelectric conversion elements PD may be located in the respective sensing areas SA (e.g., the sensing area SA of that photo sensor PS). The bank 160 may define or partition each emission area EA and each sensing area SA.

Each light-emitting element EL may include a pixel electrode 171 (e.g., an anode electrode), an emissive layer 173, and a common electrode 180 (e.g., a cathode electrode). Each photoelectric conversion element PD may include a first electrode 175 (e.g., an anode electrode), a photoelectric conversion layer 177, and a common electrode 180. According to an embodiment of the present disclosure, the light-emitting elements EL and the photoelectric conversion elements PD may share the common electrode 180.

The pixel electrode 171 of the light-emitting element EL may be located on the fifth insulating layer 153. The pixel electrode 171 may be arranged in each pixel PX. For example, the pixel electrode 171 of the light-emitting element EL may be placed in the emission area EA of the pixel PX. The pixel electrode 171 may be connected to the second anode connection electrode ANE12 through a contact hole penetrating the fifth insulating layer 153.

According to the embodiment of the present disclosure, the pixel electrode 171 of the light-emitting element EL may have a single-layer structure of molybdenum (Mo), titanium (Ti), copper (Cu) or aluminum (Al), or may have a stack of multiple films, e.g., a multi-layer structure of ITO/Mg, ITO/MgF, ITO/Ag and ITO/Ag/ITO which include indium-tin-oxide (ITO), indium-zinc-oxide (IZO), zinc oxide (ZnO), indium oxide (In₂O₃), as well as silver (Ag), magnesium (Mg), aluminum (Al), platinum (Pt), lead (Pb), gold (Au) and nickel (Ni).

In addition, the first electrode 175 of the photoelectric conversion element PD may be located on the fifth insulating layer 153. The first electrode 175 may be provided for each of the photo sensors PS. For example, the first electrode 175 of the photoelectric conversion element PD may be placed in the sensing area SA of the photo sensor PS. The first electrode 175 may be connected to the second anode connection electrode ANE22 of that photo sensor PS through a contact hole penetrating the fifth insulating layer 153.

According to the embodiment of the present disclosure, the first electrode 175 of the photoelectric conversion element PD may have, but is not limited to, a single-layer structure of molybdenum (Mo), titanium (Ti), copper (Cu) and aluminum (Al), or a multi-layer structure of ITO/Mg, ITO/MgF, ITO/Ag and ITO/Ag/ITO. It should be understood, however, that the embodiments of the present disclosure are not limited thereto. The material and/or structure of the first electrode 175 of the photoelectric conversion element PD may vary depending on the embodiments.

The bank 160 may be placed on the pixel electrode 171 and the first electrode 175. The part of the bank 160 that is above the pixel electrode 171 (e.g., on an edge of the pixel electrode 171) may be removed, forming an opening that exposes a portion of the pixel electrode 171 during the manufacturing process. The area where the exposed pixel electrode 171 and the emissive layer 173 overlap each other (or an area including the same) may be defined as the emission area EA of each pixel PX.

In addition, the bank 160 may be formed at a position overlapping the first electrode 175 (e.g., on an edge of the first electrode 175) and may include an opening exposing the first electrode 175. The opening exposing the first electrode 175 may provide space in which the photoelectric conversion layer 177 of each photo sensors PS is formed. The area where the exposed first electrode 175 and the photoelectric conversion layer 177 overlap each other (or the area including it) may be defined as the sensing area SA (or light detection area) of each photo sensor PS. For example, the bank 160 may be arranged around the emission areas EA and the sensing areas SA to surround each of the emission areas EA and the sensing areas SA.

According to the embodiment of the present disclosure, the bank 160 may include an organic insulating material such as polyacrylate resin, epoxy resin, phenolic resin, polyamide resin, polyimide resin, unsaturated polyesters resin, poly phenylen ether resin, poly phenylene sulfide resin, and benzocyclobutene (BCB). Alternatively, the bank 160 may include an inorganic material such as silicon nitride. The material of the bank 160 may vary depending on embodiments.

The emissive layer 173 may be arranged on the pixel electrode 171 of the light-emitting element EL at the base of the opening in the bank 160. The emissive layer 173 may include a high molecular weight material or a low molecular weight material. Light emitted from the emissive layer 173 may contribute to displaying images. According to an embodiment of the present disclosure, the emissive layer 173 may be disposed in each of the pixels PX, and the emissive layer 173 of each of the pixels PX may emit visible light of a color associated with the respective pixel PX. According to another embodiment, the emissive layer 173 may be a common layer shared by the pixels PX of different colors, and wavelength conversion layers corresponding to the colors (or wavelength ranges) of lights to be output from the pixels PX may be arranged in the emission areas EA of at least some of the pixels PX.

When the emissive layer 173 is made of an organic material, a hole injection layer and/or a hole transport layer may be located under each emissive layer 173, while an electron injection layer and/or an electron transport layer may be stacked on the emissive layer 173. These layers around the emissive layer 173 may be made up of a single layer or multiple layers made of organic materials.

The photoelectric conversion layer 177 may be placed on the first electrode 175 of the photoelectric conversion element PD exposed by the opening of the bank 160. The photoelectric conversion layer 177 may generate photocharges corresponding to (e.g., in proportion to) the incident light. The charges generated and accumulated in the photoelectric conversion layer 177 may be converted into electrical signals required for detecting light (e.g., fingerprint detection).

The photoelectric conversion layer 177 may include electron donors and electron acceptors. The electron donors may generate donor ions in response to light, and the electron acceptors may generate acceptor ions in response to light.

According to an embodiment of the present disclosure, when the photoelectric conversion layer 177 is made of an organic material, the electron donors may include, but is not limited to, a compound such as subphthalocyanine (SubPc) and dibutylphosphate (DBP). The electron acceptors may include, but is not limited to, a compound such as fullerene, a fullerene derivative, and perylene diimide. According to another embodiment, when the photoelectric conversion layer 177 is made of an inorganic material, the photoelectric conversion element PD may be a PN or PIN photo transistor.

When the photoelectric conversion layer 177 is made of an organic material, a hole injection layer and/or a hole transport layer may be located under each photoelectric conversion layer 177, while an electron injection layer and/or an electron transport layer may be stacked on it. These may be made up of a single layer or multiple layers made of an organic material.

According to the embodiment of the present disclosure, the sensing area SA may receive light of the same wavelength as the light generated in the emission area EA of an adjacent pixel PX as a light source. For example, the sensing area SA may receive light of the same wavelength as the light generated in the first emission area EA1 of at least one adjacent first color pixel PX1 as a light source (e.g., green light).

The common electrode 180 may be located on the emissive layer 173, the photoelectric conversion layer 177 and the bank 160. According to the embodiment of the present disclosure, the common electrode 180 may be placed across the pixels PX and the photo sensors PS such that it covers the emissive layer 173, the photoelectric conversion layer 177 and the bank 160. According to an embodiment of the present disclosure, the common electrode 180 may include, a conductive material having a low work function, for example, Li, Ca, LiF/Ca, LiF/Al, Al, Mg, Ag, Pt, Pd, Ni, Au, Nd, Ir, Cr, BaF, Ba, or a compound or mixture thereof, (e.g., a mixture of Ag and Mg). Alternatively, the common electrode 180 may include a transparent metal oxide, for example, indium-tin-oxide (ITO), indium-zinc-oxide (IZO), zinc oxide (ZnO), etc.

According to an embodiment of the present disclosure, the light-emitting elements EL and the photoelectric conversion elements PD may be arranged in substantially the same layer on the substrate SUB. For example, the light-emitting elements EL and the photoelectric conversion elements PD may be arranged in an insulating layer that is placed at the top of the panel circuit layer PCL (e.g., the fifth insulating layer 153). In addition, the configuration of at least some of the light-emitting elements EL and the configuration of at least some of the photoelectric conversion elements PD may be formed simultaneously via the same process. Accordingly, the thickness of the display device 1 including the pixels PX and the photo sensors PS can be reduced or minimized, and the fabrication process of the display device 1 can become more efficient and/or simpler.

An encapsulation layer ENL may be placed on the optical element layer OEL. According to the embodiment of the present disclosure, the encapsulation layer ENL may include at least one inorganic film and one organic film to protect each of the emissive layer 173 and the photoelectric conversion layer 177 from permeation of oxygen or moisture or particles such as dust. For example, the encapsulation layer ENL may have a stack structure of a first inorganic film 191, an organic film 193 and a second inorganic film 195. According to an embodiment of the present disclosure, the first inorganic film 191 and the second inorganic film 195 may include silicon nitride, silicon oxynitride, silicon oxide, titanium oxide, aluminum oxide, or other inorganic materials. According to an embodiment of the present disclosure, the organic film 193 may include an acrylic resin, an epoxy resin, a phenolic resin, a polyamide resin, a polyimide resin or other organic materials.

An optical filter layer OFL may be arranged on the encapsulation layer ENL. The optical filter layer OFL may include a light-shielding member LS, color filters CF, and a first overcoat layer OC1.

The light-shielding member LS may be arranged above the optical element layer OEL and the encapsulation layer ENL protecting it. The light-shielding member LS may be located in the active area AA such that it is located between the emission areas EA and/or the sensing areas SA, and may surround each of the emission areas EA and the sensing areas SA.

The light-shielding member LS may include first openings OPN1 in line with the emission areas EA of the pixels PX, and second openings OPN2 in line with the sensing areas SA of the photo sensors PS. The first openings OPN1 may be located in the respective emission areas EA and may expose at least a portion of the light-emitting element EL located in that emission area EA. The second openings OPN2 may be located in the respective sensing areas SA and may expose at least a portion of the photoelectric conversion elements PD located in that sensing area SA. The second opening OPN2 of the light-shielding member LS may correspond to a light-receiving portion of that photoelectric conversion element PD. For example, each second opening OPN2 may correspond to the light-receiving portion of the photoelectric conversion element PD exposed by the second opening OPN2.

Although the first openings OPN1 and the second openings OPN2 of the light-shielding member LS have substantially the same width and/or area as the openings of the bank 160 and are in line with the openings of the bank 160 in the example shown in FIG. 8, the embodiments of the present disclosure are not limited thereto. For example, the size (e.g., area) and/or shape of the first openings OPN1 and/or second openings OPN2 of the light-shielding member LS may be adjusted in consideration of various factors such as the light emission characteristics or viewing angle of the pixels PX, the light reception rate of the photo sensors PS, etc. For example, the opening in the light-shielding member LS may be larger or wider than the opening in the bank 160 above the emission areas EA, the sensing areas SA, or both.

The light-shielding member LS may be made of a material that can absorb and/or block light. For example, the light-shielding member LS may be formed as a photosensitive resin containing an inorganic black pigment such as carbon black or an organic black pigment.

According to an embodiment of the present disclosure, at least two color filters CF overlapping each other may be provided in place of the light-shielding member LS. For example, by arranging at least two color filters CF among the first color filter CF1, the second color filter CF2 and the third color filter CF3 at the position where the light-shielding member LS of FIG. 8 is located, it is possible to block light transmission.

The color filters CF may include first color filters CF1 that selectively transmit light of a first color, second color filters CF2 that selectively transmit light of a second color, and third color filters CF3 that selectively transmit light of a third color. The color filters CF may be arranged across the first opening OPN1 of the light-shielding member LS corresponding to each emission area EA, so that light of a particular color can be controlled to be output from each emission area EA.

The first color filters CF1 may be located in the first emission areas EA1 such that they are arranged over the light-emitting elements EL of the first color pixels PX1. For example, the first color filters CF1 may be located in the first openings OPN1 of the light-shielding member LS that is positioned above the light-emitting elements EL of the first color pixels PX1 (e.g., the first openings OPN1 of the first group corresponding to the first color pixels PX1). Each of the first color filters CF1 may be positioned above a respective light-emitting element EL that is under the respective first opening OPN1.

Although not explicitly depicted, the second color filters CF2 may be located in the second emission areas EA2 such that they are arranged over the light-emitting elements EL of the second color pixels PX2. For example, the second color filters CF2 may be located in the first openings OPN1 of the light-shielding member LS that expose the light-emitting elements EL of the second color pixels PX2 (e.g., the first openings OPN1 of the second group corresponding to the second color pixels PX2). Each of the second color filters CF2 may overlap with the light-emitting element EL that is positioned under the respective first opening OPN1.

The third color filters CF2 may be located in the third emission areas EA3 such that they are arranged over the light-emitting elements EL of the third color pixels PX3. For example, the third color filters CF3 may be located in the first openings OPN1 of the light-shielding member LS that expose the light-emitting elements EL of the third color pixels PX3 (e.g., the first openings OPN1 of the third group corresponding to the third color pixels PX3). Each of the third color filters CF3 may overlap with the light-emitting element EL exposed by the respective first opening OPN1.

According to the embodiment of the present disclosure, at least part of the light-shielding member LS may be formed under the color filters CF, and a portion of each of the color filters CF may be located on a portion of the light-shielding member LS. For example, as shown in FIG. 8, an edge of the first color filter CF1 may be located on the light-shielding member LS.

The overcoat layer OC may be a capping layer that protects the color filters CF and may include an inorganic film. For example, the overcoat layer OC may include silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, etc.

The window WDL may be placed on the optical filter layer OFL. The window WDL may be made of, e.g., a glass substrate, a plastic substrate, or a protective film, but the material is not limited thereto.

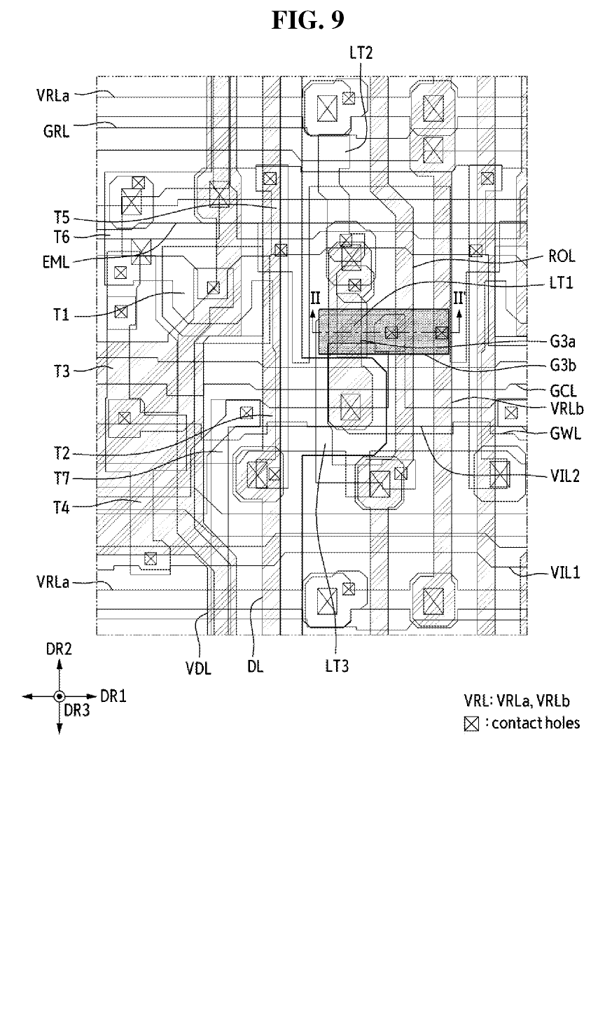

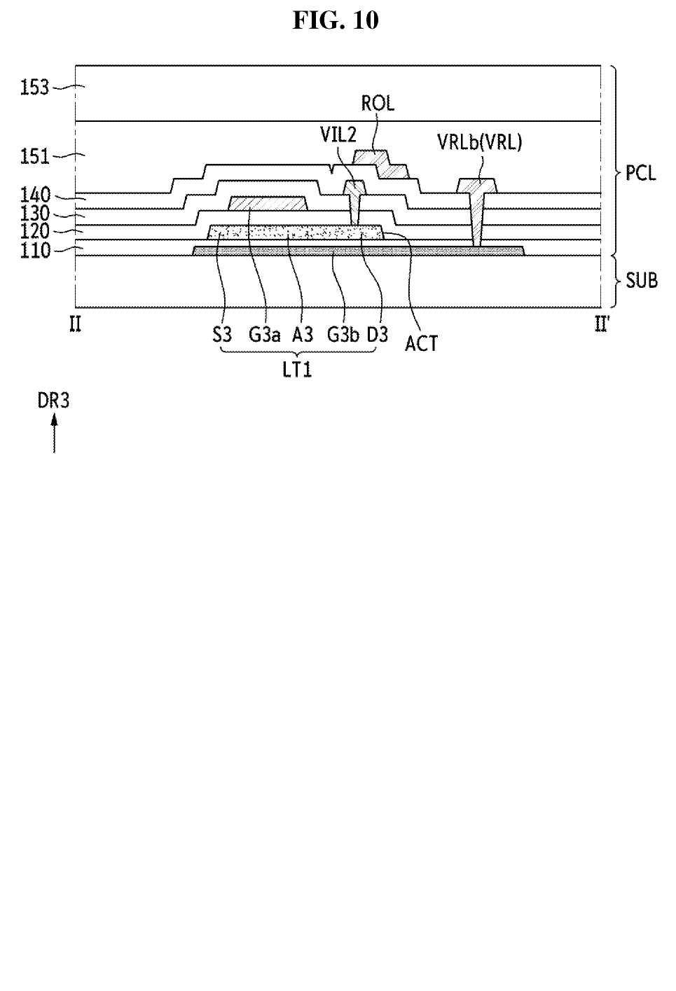

FIG. 9 is a view showing a layout of a display device according to an embodiment of the present disclosure. For example, FIG. 9 may be a layout view of the pixel and the photo sensor of FIG. 5 described above. FIG. 10 is a cross-sectional view showing an example of a cross-section of the display device 1, taken along line II - II' of FIG. 9.

As shown in FIG. 9, the display device 10 may include a first transistor T1, a second transistor T2, a third transistor T3, a fourth transistor T4, a fifth transistor T5, a sixth transistor T6, a seventh transistor T7, a first sensor transistor LT1, a second sensor transistor LT2, and a third sensor transistor LT3.

The connection relationship of the first transistor T1, the second transistor T2, the third transistor T3, the fourth transistor T4, the fifth transistor T5, the sixth transistor T6, the seventh transistor T7, the first sensor transistor LT1, the second sensor transistor LT2 and the third sensor transistor LT3 shown in FIG. 9 is the same as the connection relationship of the first transistor T1, the second transistor T2, the third transistor T3, the fourth transistor T4, the fifth transistor T5, the sixth transistor T6, the seventh transistor T7, the first sensor transistor LT1, the second sensor transistor LT2 and the third sensor transistor LT3 shown in FIG. 5.

As shown in FIG. 9, the reset voltage line VRL may include a first sub-reset voltage line VRLa and a second sub-reset voltage line VRLb that are arranged on different layers in the third direction DR3 and are electrically connected with one another. For example, the second sub-reset voltage line VRLb may be arranged on the first sub-reset voltage line VRLa such that it overlaps with the first sub-reset voltage line VRLa. An insulating layer may be arranged between the first sub-reset voltage line VRLa and the second sub-reset voltage line VRLb, and the second sub-reset voltage line VRLb may be connected to the first sub-reset voltage line VRLa through a contact hole that extends through the insulating layer.

The first sub-reset voltage line VRLa and the second sub-reset voltage line VRLb may extend in directions intersecting each other. For example, the first sub-reset voltage line VRLa may be extended in the first direction DR1, and the second sub-reset voltage line VRLb may be extended in the second direction DR2.

As shown in FIG. 10, the first sensor transistor LT1 may include a gate electrode G3a, a counter gate electrode G3b, a channel region A3, a source electrode S3and a drain electrode D3.

The counter gate electrode G3b of the first sensor transistor LT1 may be placed on the substrate SUB. For example, the opposing gate electrode G3b of the first sensor transistor LT1 may be located between the substrate SUB and a barrier layer 110.

An active layer ACT defining the channel region A3, the source electrode S3 and the drain electrode D3 of the first sensor transistor LT1 may be located on the barrier layer 110. For example, the active layer ACT may be placed between the barrier layer 110 and the first insulating layer 120. The active layer ACT may overlap with the counter gate electrode G3b of the first sensor transistor LT1. For example, the channel region A3 of the active layer ACT may overlap with the counter gate electrode G3b of the first sensor transistor LT1.

The gate electrode G3a of the first sensor transistor LT1 may be placed on the first insulating layer 120. For example, the gate electrode G3a of the first sensor transistor LT1 may be located between the first insulating layer 120 and a second insulating layer 130. The gate electrode G3a of the first sensor transistor LT1 may overlap the active layer ACT. For example, the gate electrode G3a of the first sensor transistor LT1 may overlap the channel region A3 of the active layer ACT.

A second initialization voltage line VIL2 may be placed on the second insulating layer 130. For example, the second initialization voltage line VIL2 may be located between the second insulating layer 130 and the third insulating layer 140. The second initialization voltage line VIL2 may be connected to the drain electrode D3 of the first sensor transistor LT1 through a contact hole that extends through the second insulating layer 130 and the first insulating layer 120.

A read out line ROL and a second sub-reset voltage line VRLb may be arranged on the third insulating layer 140. The second sub-reset voltage line VRLb may be connected to the counter gate electrode G3b of the first sensor transistor LT1 through a contact hole that extends through the third insulating layer 140, the second insulating layer 130, the first insulating layer 120 and the barrier layer 110. Accordingly, the counter gate electrode G3b of the first sensor transistor LT1 may be connected to the reset voltage line VRL. For example, the counter gate electrode G3b of the first sensor transistor LT1 may be connected to the first sub-reset voltage line VRLa through the second sub-reset voltage line VRLb.

It should be noted that the connection between the counter gate electrode G3b of the first sensor transistor LT1 and the reset voltage line VRL is not limited to the exact way depicted in FIG. 10 and may be modified in various ways. For example, the counter gate electrode G3b of the first sensor transistor LT1 may be connected to the reset voltage line VRL through another electrode. For example, the counter gate electrode G3b and the second sub-reset voltage line VRLb may be connected to each other by a bridge electrode that overlaps with one side of the counter gate electrode G3b and overlaps with the second sub-reset voltage line VRLb. Since the bridge electrode may be placed on the fourth insulating layer 151, one side of the bridge electrode may be connected to the counter gate electrode G3b through a contact hole that extends through the fourth insulating layer 151, the third insulating layer 140, the second insulating layer 130, the first insulating layer 120 and the barrier layer 110, while the other side of the bridge electrode may be connected to the second sub-reset voltage line VRLb through another contact hole that extends through the fourth insulating layer 151.

According to an embodiment, the doping concentration of the channel region of the first transistor T1 may be different from the doping concentration of the channel region A3 of the first sensor transistor LT1. For example, the doping concentration of the channel region A3 of the first sensor transistor LT1 may be higher or lower than the doping concentration of the channel region of the first transistor T1. In this instance, the threshold voltage of the first sensor transistor LT1 may have a value further moved in the positive direction than the threshold voltage of the first transistor T1. The first sensor transistor LT1 may include only one gate electrode G3a of the two gate electrodes G3a and G3b, or may include both the gate electrodes G3a and G3b.

According to an embodiment, the doping concentration of the channel region of the first transistor T1 may be different from the doping concentration of the channel region of the second sensor transistor LT2. For example, the doping concentration of the channel region of the second sensor transistor LT2 may be higher or lower than the doping concentration of the channel region of the first transistor T1. In this instance, the threshold voltage of the first sensor transistor LT1 may have a value closer to the positive direction than the threshold voltage of the first transistor T1.

The display device 1 according to the embodiment may be applied to a variety of electronic devices. An electronic device according to an embodiment includes the display device 1 described above, and may further include a module or device having additional features in addition to the display device 1.

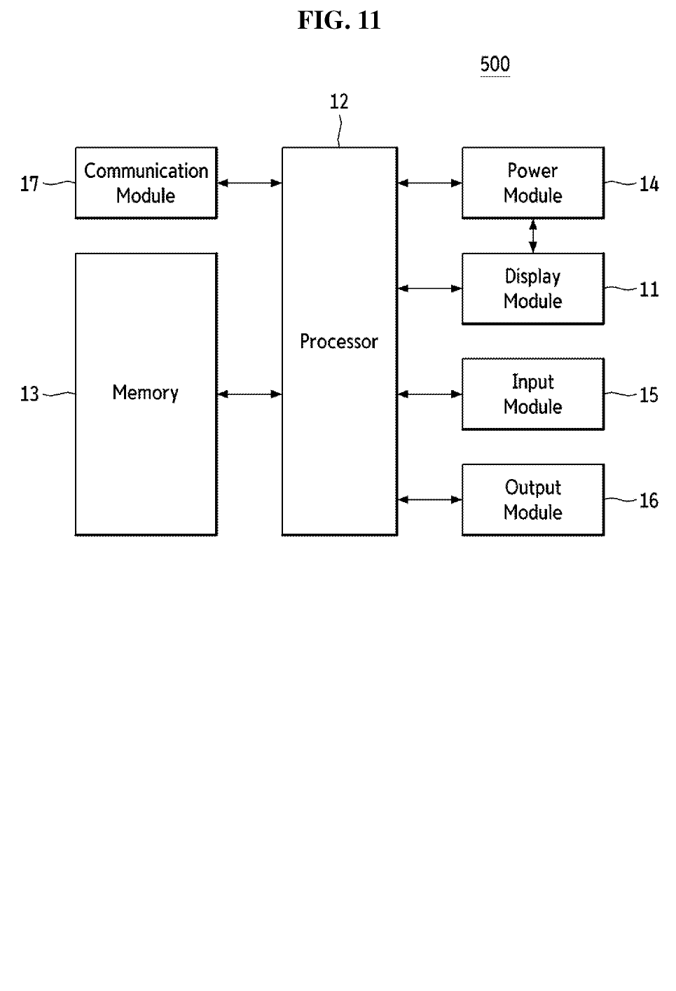

FIG. 11 is a block diagram of an electronic device according to an embodiment of the present disclosure. Referring to FIG. 11, an electronic device 500 according to an embodiment of the present disclosure may include a display module 11, a processor 12, a memory 13, and a power module 14. The electronic device 500 may further include an input module 15, a non-image output module 16, and/or a communication module 17.

The electronic device 500 may output various information in the form of images through the display module 11. When the processor 12 executes an application stored in the memory 13, image information provided by the application may be provided to the user through the display module 11. The power module 14 may include a power supply module such as a power adapter and a battery device, and a power conversion module that converts the power supplied by the power supply module to generate power required for the operation of the electronic device 500. The input module 15 may provide input information to the processor 12 and/or the display module 11. The non-image output module 16 may receive information other than images from the processor 12, such as sound, haptic and emission information, and provide it to the user. The communication module 17 is responsible for transmitting and receiving information between the electronic device 500 and an external device, and may include a receiving unit and a transmitting unit.

At least one of the elements of the electronic device 500 described above may be included in the display devices according to the embodiments described above. In addition, some of the individual modules functioning as a single module may be included in the display device while some others may be provided separately from the display device. For example, the display device may include the display module 11, and the processor 12, the memory 13 and the power module 14 may be implemented as other devices inside the electronic device 50 instead of the display device.

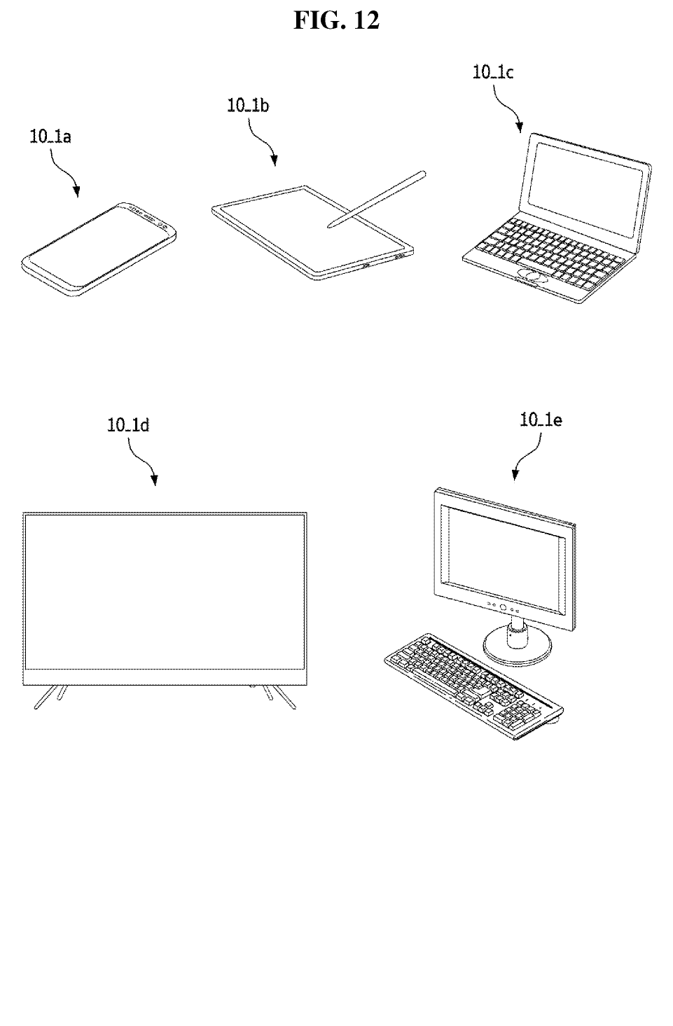

FIGS. 12, 13 and 14 are views showing electronic devices according to a variety of embodiments of the present disclosure. FIGS. 12-14 show examples of a variety of electronic devices employing the display devices 1 according to the embodiments.

FIG. 12 shows a smartphone 10_1a, a tablet PC 10_1b, a laptop computer 10_1c, a TV 10_1d, and a desktop monitor 10_1e as examples of the electronic devices.

The smartphone 10_1a may include an input module such as a touch sensor and a communication module in addition to a display module 11. The smartphone 10_1a may process information received through the communication module or other input modules and display the information through the display module of the display device.

The tablet PCs 10_1b, the laptop computer 10_1c, the TV 10_1d and the desktop monitor 10_1e may include display modules and input modules similar to the smartphone 10_1a, and may further include communication modules as desired.

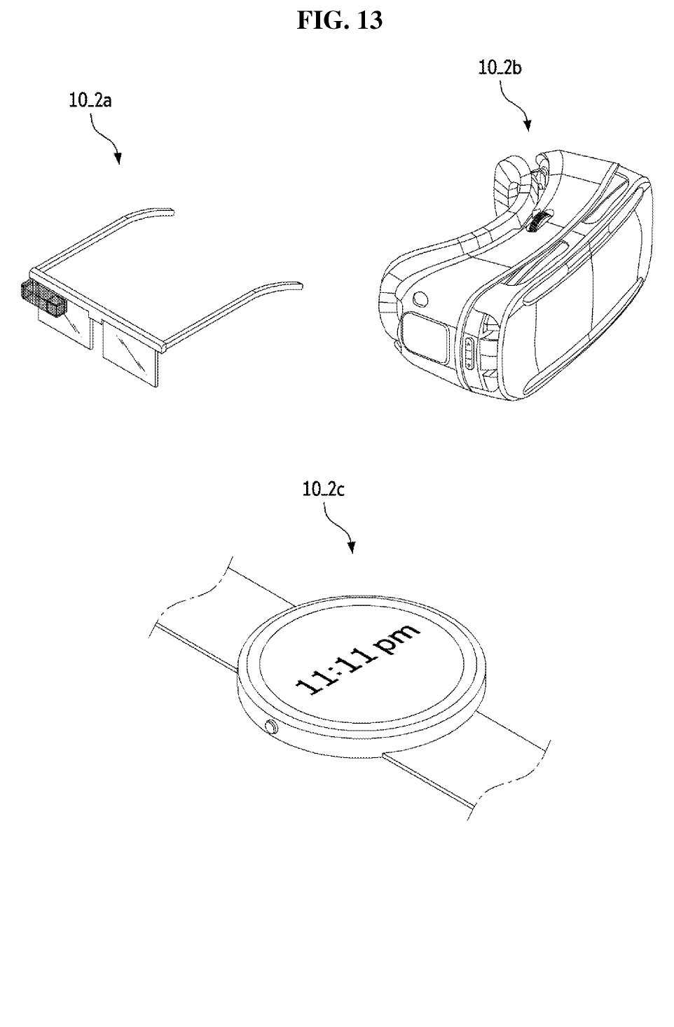

FIG. 13 shows examples of a wearable electronic device employing an electronic device including a display module. The wearable electronic devices may be smart glasses 10_2a, a head-mounted display 10_2b, a smart watch 10_2c, etc.

The smart glasses 10_2a and the head-mounted display 10_2b may include a display module that outputs display images, and a reflector that reflects the output display images and provides it to the user's eyes, thereby providing the user with images of virtual reality or augmented reality on the screen.

The smart watch 10_2c includes a biometric sensor as an input device, and may provide the user with biometric information recognized by the biometric sensor through the display module.

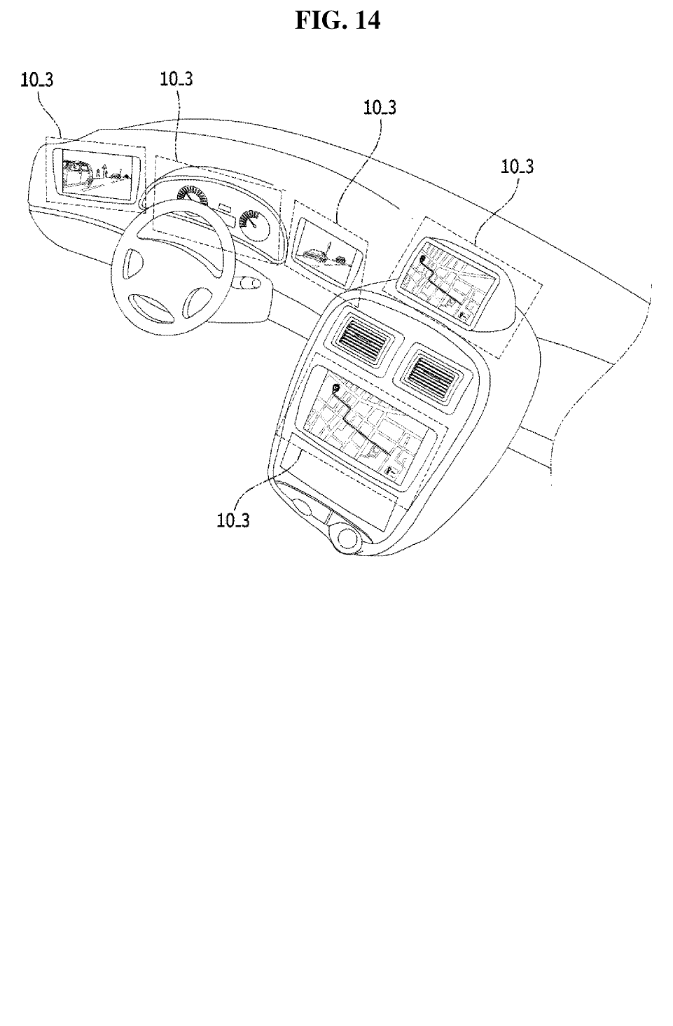

FIG. 14 shows an example of an electronic device including a display module applied to a vehicle. For example, an electronic device 10_3 may be applied to the instrument cluster, the center fascia, etc., of a vehicle, or may be applied to a center information display (CID) disposed at the dashboard of a vehicle, or may be used as a room mirror display on the behalf of the side mirrors of a vehicle.

In concluding the detailed description, those skilled in the art will appreciate that many variations and modifications can be made to the embodiments without substantially departing from the principles of the inventive concept. Therefore, the disclosed embodiments are used in a generic and descriptive sense only and not for purposes of limitation.

What is claimed is:

1. A display device comprising:
a pixel comprising a pixel circuit and a light-emitting element connected to the pixel circuit; and
a photo sensor comprising a photo sensor circuit and a photoelectric conversion element connected to the photo sensor circuit;
wherein the pixel circuit includes a first transistor that is connected to the light-emitting element;
wherein the photo sensor circuit includes a first sensor transistor that is connected to the photo sensor, and
wherein the first sensor transistor comprises a gate electrode connected to the photo sensor and a counter gate electrode connected to a reset voltage line.

2. The display device of claim 1, wherein the first sensor transistor has a threshold voltage value greater than a threshold voltage of the first transistor in a positive direction.

3. The display device of claim 1, further comprising:
a first supply voltage line connected to the pixel and transmitting a first supply voltage;
a second supply voltage line connected to the pixel and the photo sensor and transmitting a second supply voltage;
a first initialization voltage line connected to the pixel and transmitting a first initialization voltage; and
a second initialization voltage line connected to the pixel and the photo sensor and transmitting a second initialization voltage,
wherein the reset voltage line is connected to the photo sensor and transmits a reset voltage.

4. The display device of claim 3, wherein the reset voltage has a higher absolute value than the first supply voltage, the second supply voltage, the first initialization voltage, the second initialization voltage and the reset voltage.

5. The display device of claim 4, wherein the reset voltage has a negative voltage.

6. The display device of claim 3, wherein the reset voltage line comprises a first sub-reset voltage line and a second sub-reset voltage line that are arranged in different layers and are connected to each other through a contact hole,
wherein the gate electrode of the first sensor transistor is connected to an anode electrode of the photo sensor,
wherein the counter gate electrode of the first sensor transistor is connected to the second sub-reset voltage line, and
wherein a first electrode of the first sensor transistor is connected to the second initialization voltage line.

7. The display device of claim 6, wherein the photo sensor circuit further comprises:
a second sensor transistor comprising a gate electrode connected to a scan reset line, a first electrode connected to the reset voltage line, and a second electrode connected to the gate electrode of the first sensor transistor; and
a third sensor transistor comprising a gate electrode connected to a scan write line, a first electrode connected to the second electrode of the first sensor transistor, and a second electrode connected to a read-out line.

8. The display device of claim 7, wherein the pixel circuit further comprises:
a second transistor comprising a gate electrode connected to the scan write line, a first electrode connected to a data line, and a second electrode connected to a first electrode of the first transistor;
a third transistor comprising a gate electrode connected to a scan control line, a first electrode connected to the gate electrode of the first transistor, and a second electrode connected to a second electrode of the first transistor;
a fourth transistor comprising a gate electrode connected to a scan initialization line, a first electrode connected to the gate electrode of the first transistor, and a second electrode connected to the first initialization voltage line;
a fifth transistor comprising a gate electrode connected to an emission control line, a first electrode connected to the first supply voltage line, and a second electrode connected to the first electrode of the first transistor;
a sixth transistor comprising a gate electrode connected to the emission control line, a first electrode connected to the second electrode of the first transistor, and a second electrode connected to an anode electrode of the light-emitting element;
a seventh transistor comprising a gate electrode connected to a scan bias line, a first electrode connected to the second initialization voltage line, and a second electrode connected to the anode electrode of the light-emitting element;
a first capacitor connected between the first supply voltage line and the gate electrode of the first transistor; and
a second capacitor connected between the scan write line and the gate electrode of the first transistor.

9. The display device of claim 8, wherein each of the first transistor, the second transistor, the fifth transistor, the sixth transistor, the seventh transistor, the first sensor transistor and the third sensor transistor is a p-type transistor, and
wherein each of the fourth transistor, the fifth transistor and the second sensor transistor is an n-type transistor.

10. The display device of claim 1, wherein a doping concentration of the channel region of the first transistor is different from a doping concentration of the first sensor transistor.

11. The display device of claim 1, wherein the gate electrode and the counter gate electrode of the first sensor transistor face each other with an active layer between the gate electrodes.

12. The display device of claim 11, wherein the reset voltage line is connected to the counter gate electrode through a contact hole that extends through an insulating layer.

13. The display device of claim 12, further comprising:
a substrate and a barrier layer on the substrate,
wherein the counter gate electrode is located between the substrate and the barrier layer.

14. The display device of claim 13, wherein the active layer is located on the counter gate electrode such that it overlaps the counter gate electrode, and
wherein the gate electrode of the first sensor transistor is located on the active layer such that it overlaps the counter gate electrode and the active layer.

15. An electronic device comprising:
a display device including a display screen,
wherein the display device comprises:
a pixel comprising a pixel circuit and a light-emitting element connected to the pixel circuit; and
a photo sensor comprising a photo sensor circuit and a photoelectric conversion element connected to the photo sensor circuit;
wherein the pixel circuit includes a first transistor that is connected to the light-emitting element;
wherein the photo sensor circuit includes a first sensor transistor that is connected to the photo sensor, and
wherein the first sensor transistor comprises a gate electrode connected to the photo sensor and a counter gate electrode connected to a reset voltage line.

16. The electronic device of claim 15, wherein a threshold voltage of the first sensor transistor has a value greater than a threshold voltage of the first transistor in a positive direction.

17. The electronic device of claim 15, further comprising:
a first supply voltage line connected to the pixel and transmitting a first supply voltage;
a second supply voltage line connected to the pixel and the photo sensor and transmitting a second supply voltage;
a first initialization voltage line connected to the pixel and transmitting a first initialization voltage; and
a second initialization voltage line connected to the pixel and the photo sensor and transmitting a second initialization voltage,
wherein the reset voltage line is connected to the photo sensor and transmits a reset voltage.

18. The electronic device of claim 17, wherein the reset voltage has a higher absolute value than the first supply voltage, the second supply voltage, the first initialization voltage, the second initialization voltage and the reset voltage.

19. The electronic device of claim 18, wherein the reset voltage has a negative voltage.

20. The electronic device of claim 15, wherein the electronic device is a wearable device comprising one of a head mounted display, smart glasses and a smart watch.
